(19) United States
(12) Patent Application Publication
(10) Pub. No.: US 2023/0299036 A1
(43) Pub. Date: Sep. 21, 2023

(54) SEMICONDUCTOR DEVICE

(71) Applicant: ROHM CO., LTD., Kyoto-shi, Kyoto (JP)

(72) Inventors: Takumi KANDA, Kyoto-shi, Kyoto (JP); Ryosuke FUKUDA, Kyoto-shi, Kyoto (JP)

(21) Appl. No.: 18/004,443

(22) PCT Filed: Jul. 20, 2021
(86) PCT No.: PCT/JP2021/027095

§ 371 Date: Jan. 5, 2023

(30) Foreign Application Priority Data
Aug. 5, 2020 (JP) 2020-133193

(51) Int. Cl. H01L 23/00; H01L 23/495

(52) U.S. Cl. CPC H01L 24/40; H01L 23/49575; H01L 23/49582; H01L 24/37; H01L 2224/40245; H01L 2224/404; H01L 2224/37147; H01L 2224/48245; H01L 24/48; H01L 2224/73221; H01L 24/73

(57) ABSTRACT

A semiconductor device includes: a first conductive plate having a first obverse face facing in a thickness direction; a second conductive plate located apart from the first conductive plate in a first direction crossing the thickness direction and having a second obverse face facing in the same direction as the first obverse face; semiconductor elements joined to the first obverse face; and a conductive member. The semiconductor elements each include an electrode opposite to the first obverse face. The conductive member includes a main body portion, first junction portions individually and electrically joined to the electrodes of the semiconductor elements, and a second junction portion electrically joined to the second obverse face. Moreover, the conductive member includes a first connection portion connecting the main body portion and the first junction portions, and a second connection portion connecting the main body portion and the second junction portion.

### TECHNICAL FIELD

This present disclosure relates to a semiconductor device on which a plurality of semiconductor elements such as switching elements are mounted.

### BACKGROUND ART

A semiconductor device that has a plurality of switching elements mounted thereon and converts a current based on an electric signal is widely known. Such a semiconductor device is used in a power conversion circuit such as an inverter. Patent Document 1 discloses an example of a semiconductor device on which a plurality of switching elements are mounted. The semiconductor device includes a plurality of switching elements (semiconductor chips) that are joined to a first metal pattern. The plurality of switching elements each include a lower face electrode and an upper face electrode. The lower face electrodes are electrically joined to the first metal pattern. Ends of a plurality of wires are electrically joined to the respective upper face electrodes. The other ends of the plurality of wires are electrically joined to a second metal pattern that is located adjacent to the first metal pattern.

In the semiconductor device disclosed in Patent Document 1, the electrical connection between the plurality of switching elements and the second metal pattern is achieved through the plurality of wires. Therefore, the configuration of this semiconductor device is not suitable for allowing larger current to flow. Moreover, the plurality of wires are individually joined to the respective upper face electrodes of the plurality of switching elements and the second metal pattern. Therefore, because it takes time to perform joining of the plurality of wires, this is a factor that reduces the manufacturing efficiency of the semiconductor device. Therefore, improvement in these factors is desired.

### PRIOR ART DOCUMENTS

### Patent Document

Patent Document 1: JP-A-2016-72421

### SUMMARY OF THE INVENTION

### Problem to be Solved by the Invention

In light of the foregoing, the present disclosure is directed at providing a semiconductor device that can handle a larger current, and whose manufacturing efficiency can be improved.

### Means for Solving the Problem

The semiconductor device provided by the present disclosure includes: a first conductive plate having a first obverse face facing in a thickness direction; a second conductive plate that has a second obverse face facing in the same direction, in the thickness direction, as the first obverse face, and is located apart from the first conductive plate in a first direction perpendicular to the thickness direction; a plurality of semiconductor elements that are joined to the first obverse face and include electrodes that face in the same direction, in the thickness direction, as the first obverse face; and a conductive member that is electrically joined to the electrodes of the plurality of semiconductor elements and the second obverse face. The conductive member includes a main body portion, a plurality of first junction portions that are individually and electrically joined to the electrodes of the plurality of semiconductor elements, a second junction portion that is electrically joined to the second obverse face, a first connection portion that connects the main body portion and the plurality of first junction portions, and a second connection portion that connects the main body portion and the second junction portion.

### Advantages of the Invention

According to the semiconductor device according to the present disclosure, a semiconductor device that can handle a larger current, and whose manufacturing efficiency is improved can be provided.

Other features and advantages of the present disclosure will be apparent from the following detailed description based on the attached drawings.

### BRIEF DESCRIPTION OF DRAWINGS

FIG. 1 is a perspective view of a semiconductor device according to a first embodiment of the present disclosure.

FIG. 2 is a plan view of the semiconductor device illustrated in FIG. 1.

FIG. 3 is a plan view corresponding to FIG. 2, a sealing resin being made transparent.

FIG. 4 is a bottom view of the semiconductor device illustrated in FIG. 1.

FIG. 5 is a front view of the semiconductor device illustrated in FIG. 1.

FIG. 6 is a right side view of the semiconductor device illustrated in FIG. 1.

FIG. 7 is a cross-sectional view taken along line VII-VII in FIG. 3.

FIG. 8 is a cross-sectional view taken along line VIII-VIII in FIG. 3.

FIG. 9 is a cross-sectional view taken along line IX-IX in FIG. 3.

FIG. 10 is a cross-sectional view taken along line X-X in FIG. 3.

FIG. 11 is a cross-sectional view taken along line XI-XI in FIG. 3.

FIG. 12 is a plan view of a first conductive member of the semiconductor device illustrated in FIG. 1.

FIG. 13 is a plan view of a second conductive member of the semiconductor device illustrated in FIG. 1.

FIG. 14 is an enlarged view of a part of FIG. 3.

FIG. 15 is an enlarged view of a part of FIG. 7.

FIG. 16 is an enlarged view of a part of FIG. 3.

FIG. 17 is an enlarged view of a part of FIG. 8.

FIG. 18 is an enlarged view of a part of FIG. 7.

FIG. 19 is a perspective view of a semiconductor device according to a second embodiment of the present disclosure.

FIG. 20 is a perspective view corresponding to FIG. 19, illustration of a sealing resin being omitted.

FIG. 21 is a perspective view corresponding to FIG. 19, illustration of the sealing resin and a second conductive member being omitted.

FIG. 22 is a plan view of the semiconductor device illustrated in FIG. 19.

FIG. 23 is a plan view corresponding to FIG. 22, the sealing resin being made transparent.

FIG. 24 is an enlarged view of a part of FIG. 23.

FIG. 25 is a plan view corresponding to FIG. 22, illustration of the sealing resin and the second conductive member being omitted.

FIG. 26 is an enlarged view of a part of FIG. 25.

FIG. 27 is a right side view of the semiconductor device illustrated in FIG. 19.

FIG. 28 is a bottom view of the semiconductor device illustrated in FIG. 19.

FIG. 29 is a rear view of the semiconductor device illustrated in FIG. 19.

FIG. 30 is a front view of the semiconductor device illustrated in FIG. 19.

FIG. 31 is a cross-sectional view taken along line XXXI-XXXI in FIG. 23.

FIG. 32 is a cross-sectional view taken along line XXXII-XXXII in FIG. 23.

FIG. 33 is an enlarged view of a part of FIG. 32.

FIG. 34 is a cross-sectional view taken along line XXXIV-XXXIV in FIG. 23.

FIG. 35 is a cross-sectional view taken along line XXXV-XXXV in FIG. 23.

FIG. 36 is a cross-sectional view taken along line XXXVI-XXXVI in FIG. 23.

FIG. 37 is a circuit diagram of the semiconductor device illustrated in FIG. 19.

### MODE FOR CARRYING OUT THE INVENTION

Embodiments for implementing the present disclosure will be described based on the attached drawings.

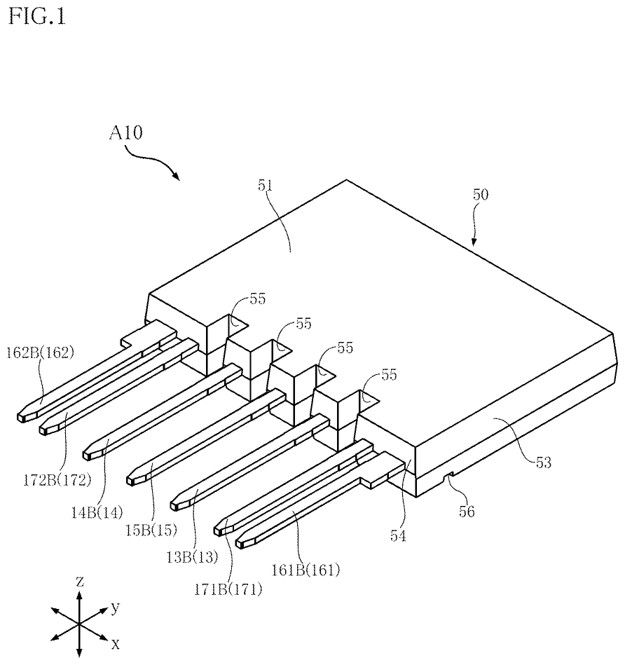

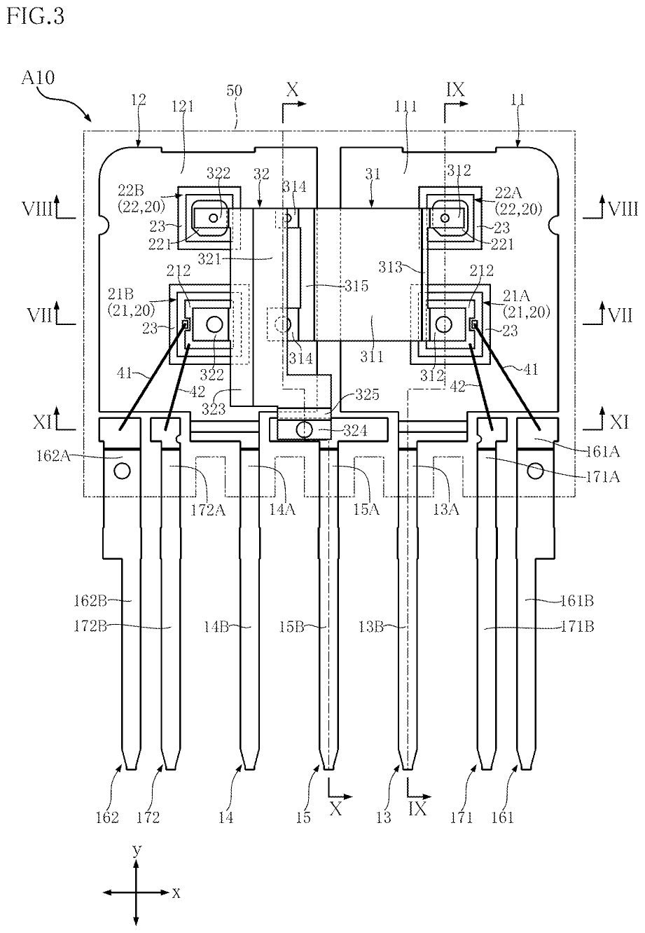

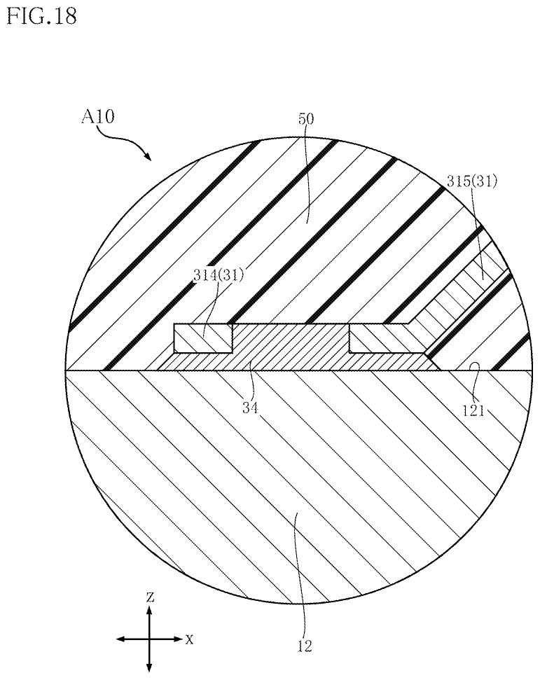

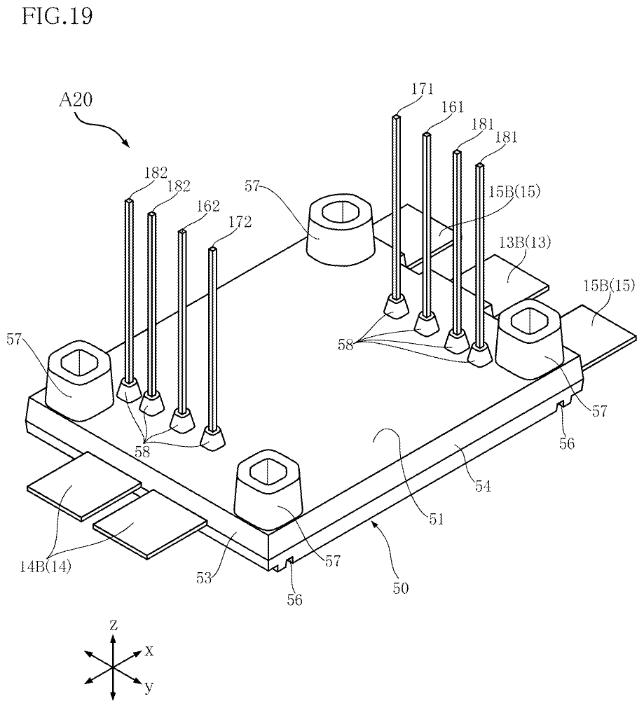

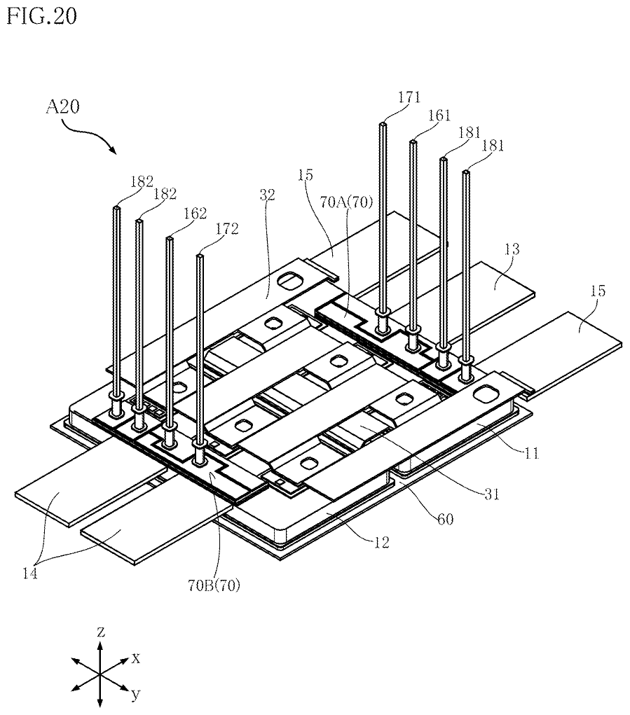

A semiconductor device A10 according to a first embodiment of the present disclosure will be described based on FIGS. 1 to 18. The semiconductor device A10 includes a first conductive plate 11, a second conductive plate 12, a first input terminal 13, an output terminal 14, a second input terminal 15, a plurality of semiconductor elements 20, a die bonding layer 23, a first conductive member 31, a plurality of first junction layers 33, a second junction layer 34, and a sealing resin 50. In the semiconductor device A10, the plurality of semiconductor elements 20 include a pair of switching elements 21 and a pair of protection elements 22. Moreover, the semiconductor device A10 includes a first gate terminal 161, a second gate terminal 162, a first detection terminal 171, a second detection terminal 172, a second conductive member 32, a plurality of third junction layers 35, a fourth junction layer 36, a pair of gate wires 41, and a pair of detection wires 42. Here, in FIG. 3, to facilitate understanding, the sealing resin 50 is made transparent. In FIG. 3, the sealing resin 50 being made transparent is shown by imaginary lines (two-dot chain lines). In FIG. 3, a line IX-IX and a line X-X are shown by one-dot chain lines.

In the description of the semiconductor device A10, the thickness direction of the first conductive plate 11 and the second conductive plate 12 is called as a “thickness direction z”, for convenience. A direction perpendicular to the thickness direction z is called as a “first direction x”. A direction perpendicular to both of the thickness direction z and the first direction x is called as a “second direction y”.

The semiconductor device A10 converts a DC power supply voltage applied between the first input terminal 13 and the second input terminal 15 to AC power by the pair of switching elements 21. The AC power generated by conversion is input to a power supply target such as a motor from the output terminal 14. The semiconductor device A10 is used as a power conversion circuit such as an inverter, for example.

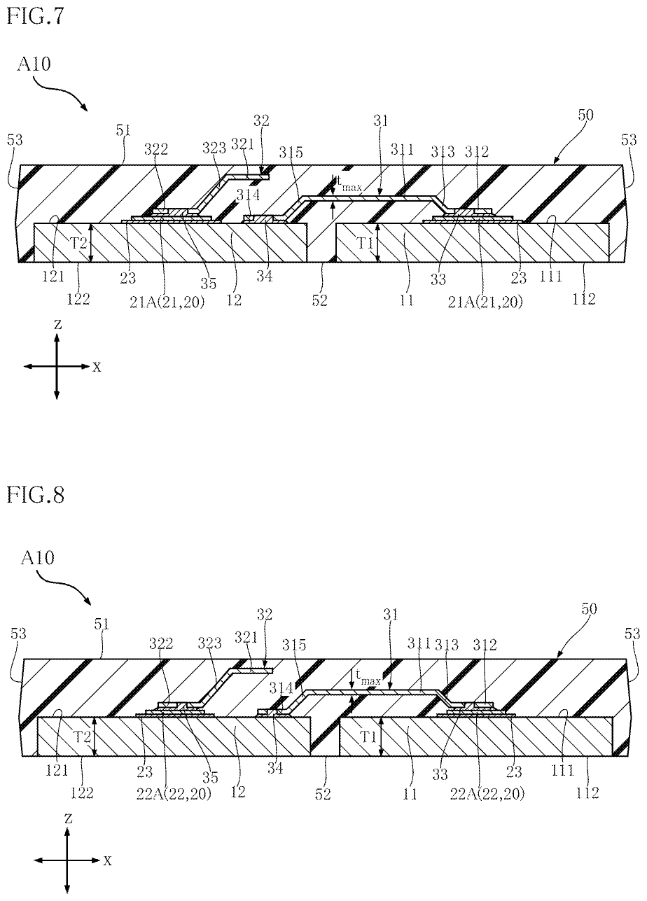

As shown in FIGS. 3, 7, and 8, the first conductive plate 11 is a conductive member on which one switching element 21 (later-described first element 21A) of the pair of switching elements 21 and one protection element 22 (later-described first diode 22A) of the pair of protection elements 22 are mounted. The first conductive plate 11 is formed by a lead frame along with the second conductive plate 12, the first input terminal 13, the output terminal 14, the second input terminal 15, the first gate terminal 161, the second gate terminal 162, the first detection terminal 171, and the second detection terminal 172. The lead frame is made of copper (Cu) or copper alloy. Therefore, the composition of each of the first conductive plate 11, the second conductive plate 12, the first input terminal 13, the output terminal 14, the second input terminal 15, the first gate terminal 161, the second gate terminal 162, the first detection terminal 171, and the second detection terminal 172 includes copper (that is, each member contains copper). The first conductive plate 11 has a first obverse face 111 and a first reverse face 112. The first obverse face 111 faces in the thickness direction z. The later-described first element 21A and first diode 22A are mounted on the first obverse face 111. The first reverse face 112 faces, in the thickness direction z, the direction opposite to the first obverse face 111. Tin (Sn) plating is applied to the first reverse face 112, for example. As shown in FIGS. 7 and 8, the thickness T1 of the first conductive plate 11 is larger than the maximum thickness tₘₐₓ of the first conductive member 31.

As shown in FIGS. 3, 7, and 8, the second conductive plate 12 is a conductive member on which the other switching element 21 (later-described second element 21B) of the pair of switching elements 21, the other protection element 22 (later-described second diode 22B) of the pair of protection elements 22 are mounted. The second conductive plate 12 is located apart from the first conductive plate 11 in the first direction x. The second conductive plate 12 has a second obverse face 121 and a second reverse face 122. The second obverse face 121 faces the same direction as the first obverse face 111 in the thickness direction z. The later-described second element 21B and second diode 22B are mounted on the second obverse face 121. The second reverse face 122 faces, in the thickness direction z, the direction opposite to the second obverse face 121. Tin plating is applied to the second reverse face 122, for example. As shown in FIGS. 7 and 8, the thickness T2 of the second conductive plate 12 is larger than the maximum thickness tₘₐₓ of the first conductive member 31.

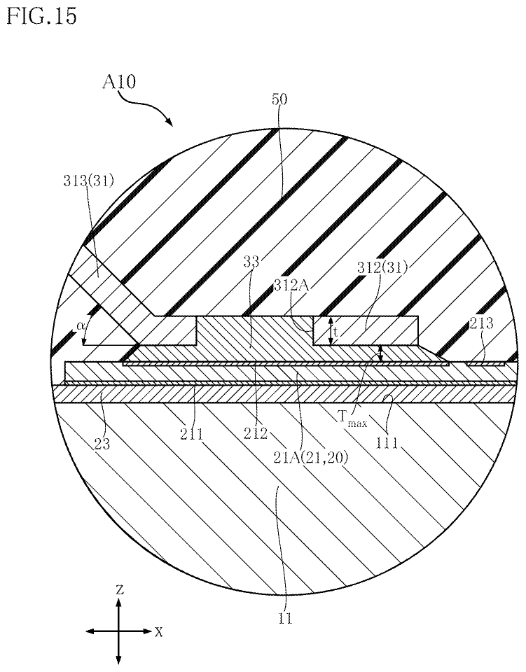

As shown in FIGS. 3 and 7, the pair of switching elements 21 includes the first element 21A and the second element 21B. The first element 21A is joined to the first obverse face 111 of the first conductive plate 11. The second element 21B is joined to the second obverse face 121 of the second conductive plate 12. The pair of switching elements 21 are MOS FETs (Metal-Oxide-Semiconductor Field-Effect Transistor), for example. The semiconductor device A10 will be described assuming that the pair of switching elements 21 are n-channel type MOS FETs having a vertical structure. The pair of switching elements 21 each include a compound semiconductor substrate. The compound semiconductor substrate contains silicon carbide (SiC). In other cases, the compound semiconductor substrate may include gallium nitride (GaN). As shown in FIG. 15, the pair of switching elements 21 each include a first electrode 211, a second electrode 212, and a third electrode 213.

As shown in FIG. 15, the first electrode 211 opposes either the first obverse face 111 of the first conductive plate 11 or the second obverse face 121 of the second conductive plate 12. A voltage corresponding to power to be converted is applied to the first electrode 211. That is, the first electrode 211 corresponds to a drain electrode.

As shown in FIG. 15, the second electrode 212 is provided on a side in the direction that the first obverse face 111 of the first conductive plate 11 faces in the thickness direction z, that is, on the side opposite to the first electrode 211. A current corresponding to the power obtained by conversion performed by one of the pair of switching elements 21 flows through the second electrode 212. That is, the second electrode 212 corresponds to a source electrode. The second electrode 212 includes a plurality of metal plating layers. The second electrode 212 includes a nickel (Ni) plating layer and a gold (Au) plating layer layered on the nickel plating layer. In other cases, the second electrode 212 may include a nickel plating layer, a palladium (Pd) plating layer layered on the nickel plating layer, and a gold plating layer layered on the palladium plating.

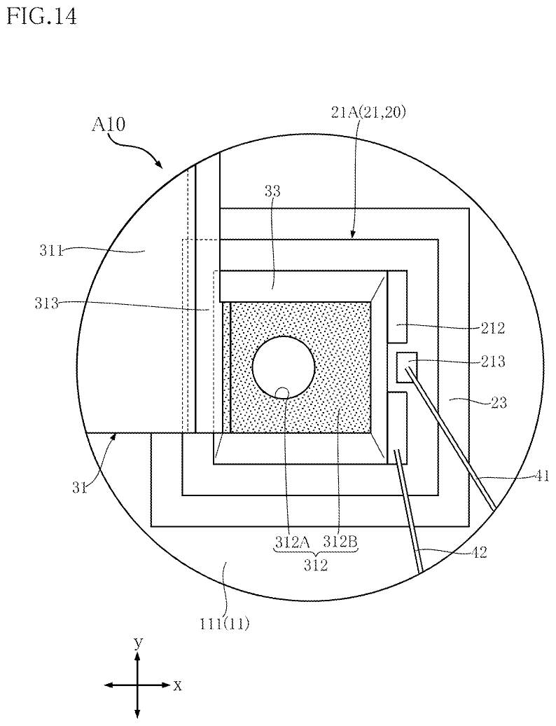

As shown in FIGS. 14 and 15, the third electrode 213 is provided on the same side as the second electrode 212, in the thickness direction z, and is located apart from the second electrode 212. A gate voltage for driving one of the pair of switching elements 21 is applied to the third electrode 213. That is, the third electrode 213 corresponds to a gate electrode. The pair of switching elements 21 each perform conversion, based on the gate voltage, such that a current corresponding to the voltage applied to the first electrode 211 is allowed to flow. The area of the third electrode 213 viewed along the thickness direction z is smaller than the area of the second electrode 212.

As shown in FIGS. 3 and 8, the pair of protection elements 22 includes the first diode 22A and the second diode 22B. The first diode 22A is joined to the first obverse face 111 of the first conductive plate 11. The second diode 22B is joined to the second obverse face 121 of the second conductive plate 12. The pair of protection elements 22 are Schottky-barrier diodes, for example. The first diode 22A is connected in parallel to the first element 21A. The second diode 22B is connected in parallel to the second element 21B. The pair of protection elements 22 are each a commonly-called flyback diode that, when a reverse bias is applied to a switching element 21 connected in parallel thereto, blocks the flow of current through the switching element 21 but allows a current to flow through the protection element 22. As shown in FIG. 17, the protection elements 22 each include an upper face electrode 221 and a lower face electrode 222.

As shown in FIG. 17, the upper face electrode 221 is provided on a side in the direction that the first obverse face 111 of the first conductive plate 11 faces in the thickness direction z, (upper side in FIG. 17). In each of the protection elements 22, the upper face electrode 221 is electrically connected to the second electrode 212 of one of the pair of switching elements 21 that is connected in parallel to the corresponding protection element 22. That is, the upper face electrodes 221 correspond to anode electrodes.

As shown in FIG. 17, the lower face electrode 222 is provided on a side opposite to the upper face electrode 221, in the thickness direction z. In each of the protection elements 22, the lower face electrode 222 is electrically connected to the first electrode 211 of one of the pair of switching elements 21 that is connected in parallel to the corresponding protection element 22. That is, the lower face electrodes 222 correspond to cathode electrodes.

As shown in FIG. 3, the first element 21A and the first diode 22A are arranged along the second direction y on the first obverse face 111 of the first conductive plate 11. The second element 21B and the second diode 22B are arranged along the second direction y on the second obverse face 121 of the second conductive plate 12. In this way, the plurality of semiconductor elements 20 are arranged along the second direction y in the semiconductor device A10.

As shown in FIGS. 3, 15, and 18, the die bonding layer 23 includes portions that are located between the first obverse face 111 of the first conductive plate 11 or the second obverse face 121 of the second conductive plate 12 and the first electrodes 211 of the pair of switching elements 21 or the lower face electrodes 222 of the pair of protection elements 22. The die bonding layer 23 has conductivity. The die bonding layer 23 is made of lead-free solder, for example. In other cases, the die bonding layer 23 may be made of lead solder. The die bonding layer 23 electrically joins the first electrode 211 of the first element 21A and the lower face electrode 222 of the first diode 22A to the first obverse face 111. With this, the first electrode 211 of the first element 21A and the lower face electrode 222 of the first diode 22A are electrically connected to the first conductive plate 11. The die bonding layer 23 electrically joins the first electrode 211 of the second element 21B and the lower face electrode 222 of the second diode 22B to the second obverse face 121. With this, the first electrode 211 of the second element 21B and the lower face electrode 222 of the second diode 22B are electrically connected to the second conductive plate 12.

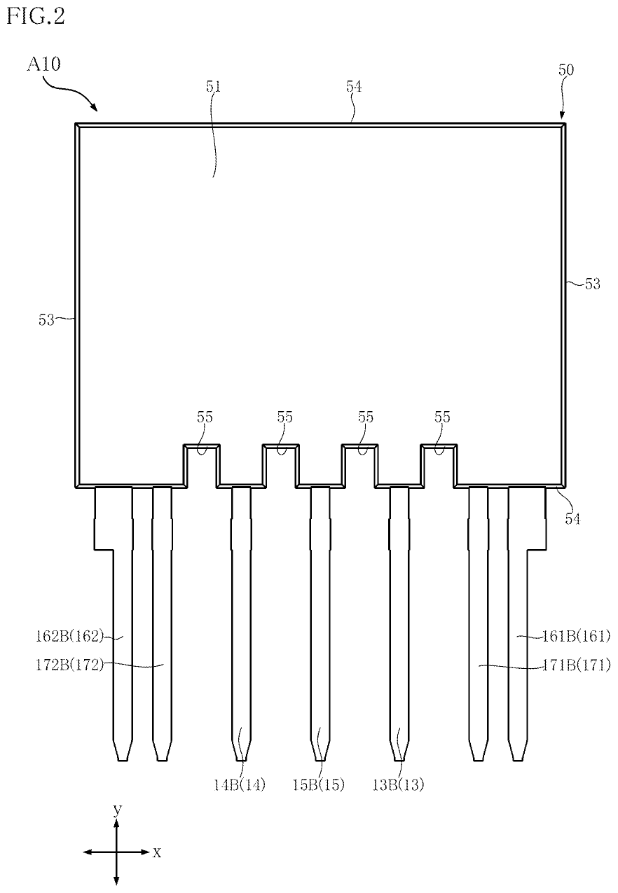

The first input terminal 13 includes a portion that extends along the second direction y, and is connected to the first conductive plate 11, as shown in FIG. 3. Therefore, the first input terminal 13 is electrically connected to the first conductive plate 11. The first input terminal 13 is a P terminal (positive electrode) to which a DC power supply voltage, regarding which power conversion is performed, is applied. The first input terminal 13 includes a covered portion 13A and an exposed portion 13B. As shown in FIG. 9, the covered portion 13A is connected to the first conductive plate 11 and is covered by the sealing resin 50. The covered portion 13A is bent when viewed along the first direction x. As shown in FIGS. 2 to 5, the exposed portion 13B is connected to the covered portion 13A and is exposed from the sealing resin 50. The exposed portion 13B extends so as to be apart from the first conductive plate 11 in the second direction y. Tin-plating is applied to the surface of the exposed portion 13B, for example.

The output terminal 14 includes a portion that extends along the second direction y, and is connected to the second conductive plate 12, as shown in FIG. 3. Therefore, the output terminal 14 is electrically connected to the second conductive plate 12. The AC power obtained by conversion performed by the pair of switching elements 21 is output from the output terminal 14. The output terminal 14 includes a covered portion 14A and an exposed portion 14B. The covered portion 14A is connected to the second conductive plate 12 and is covered by the sealing resin 50 (refer to FIG. 11). The covered portion 14A is bent when viewed along the first direction x, similarly to the covered portion 13A of the first input terminal 13. As shown in FIGS. 2 to 5, the exposed portion 14B is connected to the covered portion 14A and is exposed from the sealing resin 50. The exposed portion 14B extends so as to be apart from the second conductive plate 12 in the second direction y. Tin-plating is applied to the surface of the exposed portion 14B, for example.

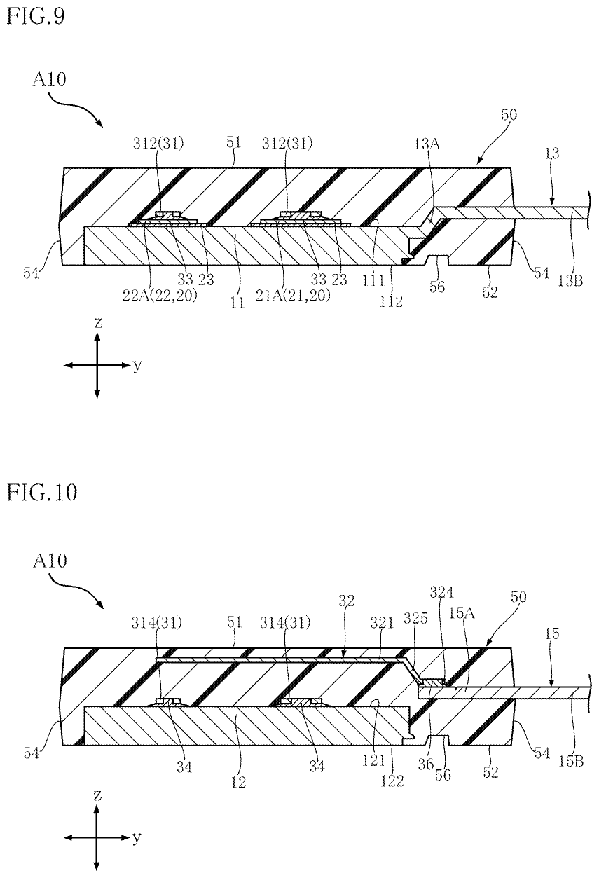

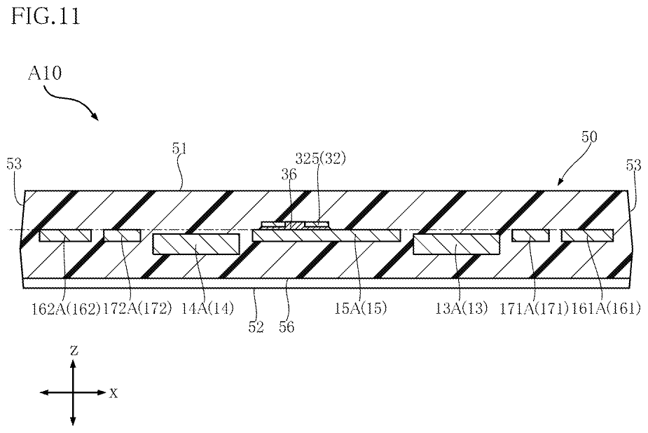

As shown in FIG. 3, the second input terminal 15 is located apart from both of the first conductive plate 11 and the second conductive plate 12 in the second direction y, and is located between the first input terminal 13 and the output terminal 14 in the first direction x. The second input terminal 15 extends along the second direction y. The second input terminal 15 is electrically connected to the second electrode 212 of the second element 21B and the upper face electrode 221 of the second diode 22B. The second input terminal 15 is an N terminal (negative electrode) to which a DC power supply voltage, regarding which power conversion is performed, is applied. The second input terminal 15 includes a covered portion 15A and an exposed portion 15B. As shown in FIG. 10, the covered portion 15A is covered by the sealing resin 50. As shown in FIGS. 2 to 5, the exposed portion 15B is connected to the covered portion 15A and is exposed from the sealing resin 50. The exposed portion 15B extends so as to be apart from both of the first conductive plate 11 and the second conductive plate 12 in the second direction y. Tin-plating is applied to the surface of the exposed portion 15B, for example.

As shown in FIG. 3, the first gate terminal 161 is located apart from the first conductive plate 11 in the second direction y, and is located on one end in the first direction x. As shown in FIG. 3, the second gate terminal 162 is located apart from the second conductive plate 12 in the second direction y, and is located on the other end in the first direction x. The first gate terminal 161 is electrically connected to the third electrode 213 of the first element 21A. A gate voltage for driving the first element 21A is applied to the first gate terminal 161. The second gate terminal 162 is electrically connected to the third electrode 213 of the second element 21B. A gate voltage for driving the second element 21B is applied to the second gate terminal 162.

As shown in FIG. 3, the first gate terminal 161 includes a covered portion 161A and an exposed portion 161B. As shown in FIG. 11, the covered portion 161A is covered by the sealing resin 50. As shown in FIGS. 2 to 5, the exposed portion 161B is connected to the covered portion 161A and is exposed from the sealing resin 50. The exposed portion 161B extends so as to be apart from the first conductive plate 11 in the second direction y. Tin-plating is applied to the surface of the exposed portion 161B, for example.

As shown in FIG. 3, the second gate terminal 162 includes a covered portion 162A and an exposed portion 162B. As shown in FIG. 11, the covered portion 162A is covered by the sealing resin 50. As shown in FIGS. 2 to 5, the exposed portion 162B is connected to the covered portion 162A and is exposed from the sealing resin 50. The exposed portion 162B extends so as to be apart from the second conductive plate 12 in the second direction y. Tin-plating is applied to the surface of the exposed portion 162B, for example.

As shown in FIG. 3, the first detection terminal 171 is located apart from the first conductive plate 11 in the second direction y, and is located between the first input terminal 13 and the first gate terminal 161 in the first direction x. As shown in FIG. 3, the second detection terminal 172 is located apart from the second conductive plate 12 in the second direction y, and is located between the output terminal 14 and the second gate terminal 162 in the first direction x. The first detection terminal 171 is electrically connected to the second electrode 212 of the first element 21A. A voltage corresponding to the current flowing through the second electrode 212 of the first element 21A is applied to the first detection terminal 171. The second detection terminal 172 is electrically connected to the second electrode 212 of the second element 21B. A voltage corresponding to the current flowing through the second electrode 212 of the second element 21B is applied to the second detection terminal 172.

As shown in FIG. 3, the first detection terminal 171 includes a covered portion 171A and an exposed portion 171B. As shown in FIG. 11, the covered portion 171A is covered by the sealing resin 50. As shown in FIGS. 2 to 5, the exposed portion 171B is connected to the covered portion 171A and is exposed from the sealing resin 50. The exposed portion 171B extends so as to be apart from the first conductive plate 11 in the second direction y. Tin-plating is applied to the surface of the exposed portion 171B, for example.

As shown in FIG. 3, the second detection terminal 172 includes a covered portion 172A and an exposed portion 172B. As shown in FIG. 11, the covered portion 172A is covered by the sealing resin 50. As shown in FIGS. 2 to 5, the exposed portion 172B is connected to the covered portion 172A and is exposed from the sealing resin 50. The exposed portion 172B extends so as to be apart from the second conductive plate 12 in the second direction y. Tin-plating is applied to the surface of the exposed portion 172B, for example.

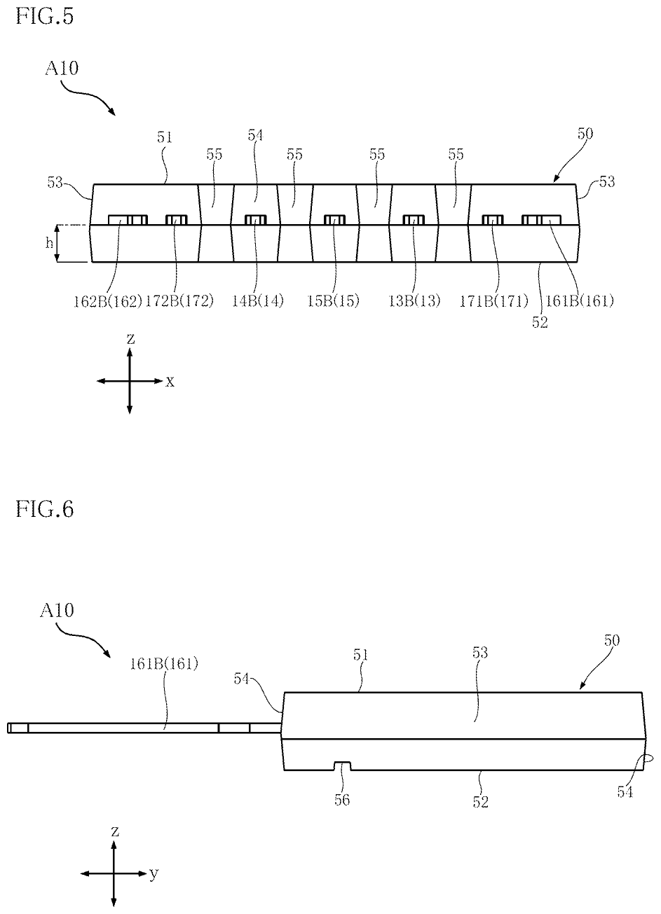

As shown in FIG. 5, in the semiconductor device A10, the heights h of the exposed portion 13B of the first input terminal 13, the exposed portion 14B of the output terminal 14, and the exposed portion 15B of the second input terminal 15 are the same. Moreover, the thicknesses of these are the same. Therefore, at least a portion of the second input terminal 15 (exposed portion 15B) overlaps with the first input terminal 13 and the output terminal 14 viewed along the first direction x (refer to FIG. 6).

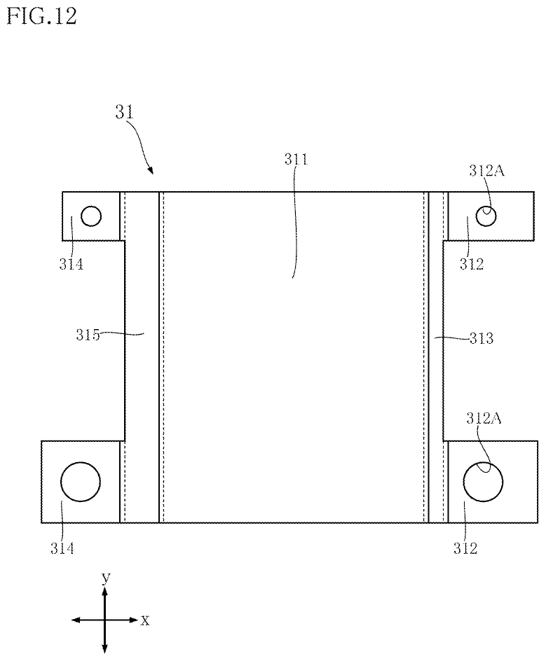

As shown in FIG. 3, the first conductive member 31 is electrically joined to the second electrode 212 of the first element 21A, the upper face electrode 221 of the first diode 22A, and the second obverse face 121 of the second conductive plate 12. With this, the second electrode 212 of the first element 21A and the upper face electrode 221 of the first diode 22A are, in a state of being electrically connected to each other, electrically connected to the second conductive plate 12. The first conductive member 31 contains copper. In the semiconductor device A10, the first conductive member 31 is a metal clip. As shown in FIG. 12, the first conductive member 31 includes a main body portion 311, a plurality of first junction portions 312, a first connection portion 313, a second junction portion 314, and a second connection portion 315.

As shown in FIG. 12, the main body portion 311 is a main portion of the first conductive member 31. The main body portion 311 extends along the second direction y. As shown in FIGS. 7 and 8, the main body portion 311 is in parallel with the first obverse face 111 of the first conductive plate 11. As shown in FIG. 3, a portion of the main body portion 311 overlaps with the first obverse face 111 viewed along the thickness direction z.

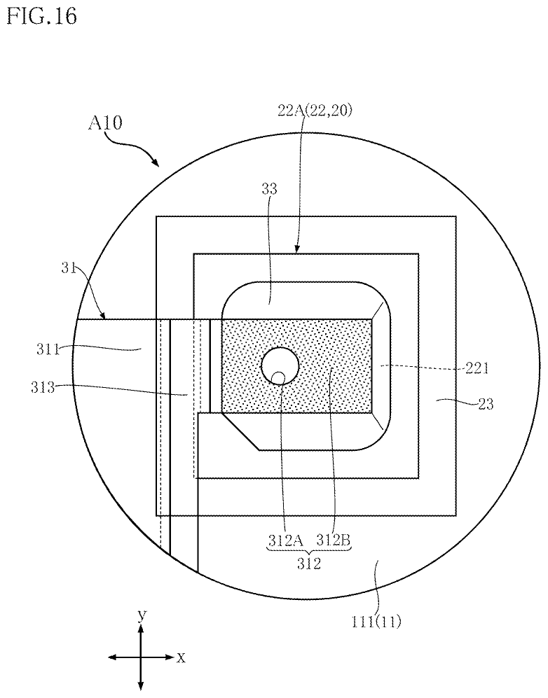

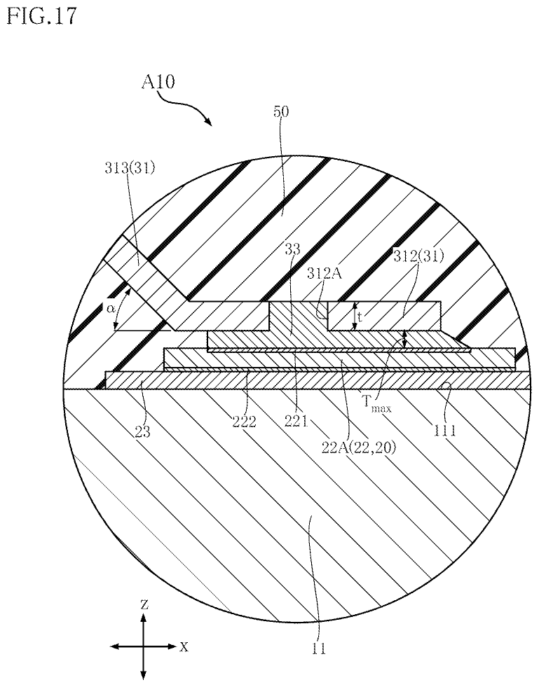

As shown in FIGS. 3, 7, and 8, the plurality of first junction portions 312 are individually and electrically joined to the second electrode 212 of the first element 21A and the upper face electrode 221 of the first diode 22A. The plurality of first junction portions 312 each oppose either the second electrode 212 of the first element 21A or the upper face electrode 221 of the first diode 22A. As shown in FIGS. 14 and 16, the plurality of first junction portions 312 each include an opening 312A. The openings 312A each pass through one of the plurality of first junction portions 312 in the thickness direction z. The openings 312A are circular viewed along the thickness direction z. The opening area of each opening 312A is 0.25 mm². The plurality of first junction portions 312 each include an overlapping area 312B. The overlapping areas 312B each include, viewed along the thickness direction z, an area that overlaps with either the second electrode 212 of the first element 21A or the upper face electrode 221 of the first diode 22A (note that the openings 312A are excluded). The areas of the overlapping areas 312B, viewed along the thickness direction z, are more than 70% of the respective areas of the second electrode 212 of the first element 21A and the upper face electrode 221 of the first diode 22A.

As shown in FIGS. 7 and 12, the first connection portion 313 connects the main body portion 311 and the plurality of first junction portions 312. As shown in FIG. 7, the first connection portion 313 is inclined, viewed along the second direction y, in a direction away from the first obverse face 111 of the first conductive plate 11 while extending from the plurality of first junction portions 312 toward the main body portion 311. The acute angle a (refer to FIGS. 15 and 17) formed between each of the plurality of first junction portions 312 and the corresponding first connection portion 313, viewed along the second direction y, is 30° or more and 60° or less.

As shown in FIGS. 3, 10, and 11, the second junction portion 314 is electrically joined to the second obverse face 121 of the second conductive plate 12. The second junction portion 314 opposes the second obverse face 121. In the semiconductor device A10, the second junction portion 314 includes two areas that are separated from each other in the second direction y.

As shown in FIGS. 7, 8, and 12, the second connection portion 315 connects the main body portion 311 and the second junction portion 314. The second connection portion 315 is inclined, viewed along an in-plane direction (second direction y in the semiconductor device A10) of the second obverse face 121 of the second conductive plate 12, away from the second obverse face 121 while extending from the second junction portion 314 toward the main body portion 311.

As shown in FIGS. 15 and 17, the plurality of first junction layers 33 each include a potion located between the second electrode 212 of the first element 21A or the upper face electrode 221 of the first diode 22A and corresponding opposing one of the plurality of first junction portions 312 of the first conductive member 31. The plurality of first junction layers 33 have conductivity. The plurality of first junction layers 33 are made of lead-free solder, for example. In other cases, the plurality of first junction layers 33 are made of lead solder. The plurality of first junction layers 33 individually and electrically join the plurality of first junction portions 312 to the second electrode 212 of the first element 21A and the upper face electrode 221 of the first diode 22A. Therefore, the first conductive member 31 is electrically joined to the second electrode 212 of the first element 21A and the upper face electrode 221 of the first diode 22A by the plurality of first junction layers 33. As shown in FIGS. 14 and 16, the plurality of first junction layers 33 each include a portion that extends outward, viewed along the thickness direction z, from the overlapping area 312B of one of the plurality of first junction portions 312. A fillet is formed in each of the first junction layers 33 that extend outward from the overlapping areas 312B of the plurality of first junction portions 312. As shown in FIGS. 14 to 17, each fillet is shaped such that, as each first junction layer 33, which is made of solder, extends outward from the corresponding overlapping area 312B, the size of the fillet in the thickness direction z gradually decreases, that is, the upper surface of the fillet is inclined toward the surface of the second electrode 212 of the first element 21A or the upper face electrode 221 of the first diode 22A.

As shown in FIGS. 15 and 17, the plurality of first junction layers 33 are individually in contact with the plurality of first junction portions 312. Moreover, the plurality of first junction layers 33 are also in contact with inner circumferential surfaces of the first junction portions 312 that define the respective openings 312A of the plurality of first junction portions 312. Therefore, the plurality of first junction layers 33 each include a portion that is embedded in one of the openings 312A of the plurality of first junction portions 312. The thickness t of the plurality of first junction portions 312 is 0.1 mm or more and twice the maximum thickness Tₘₐₓ of the plurality of first junction layers 33 or less. Here, the maximum thickness Tₘₐₓ of each of the plurality of first junction layers 33 is the maximum thickness of the portions of the first junction layer 33 excluding the portion embedded in the opening 312A. The maximum thickness Tₘₐₓ of each of the plurality of first junction layers 33 is larger than the thickness of each of the plurality of semiconductor elements 20.

As shown in FIGS. 8 and 16, the second junction layer 34 includes a portion that is located between the second obverse face 121 of the second conductive plate 12 and the opposing second junction portion 314 of the first conductive member 31. The second junction layer 34 has conductivity. The second junction layer 34 is made of lead-free solder, for example. In other cases, the second junction layer 34 may be made of lead solder. The second junction layer 34 electrically joins the second junction portion 314 and the second obverse face 121. Therefore, the first conductive member 31 is electrically joined to the second obverse face 121 by the second junction layer 34.

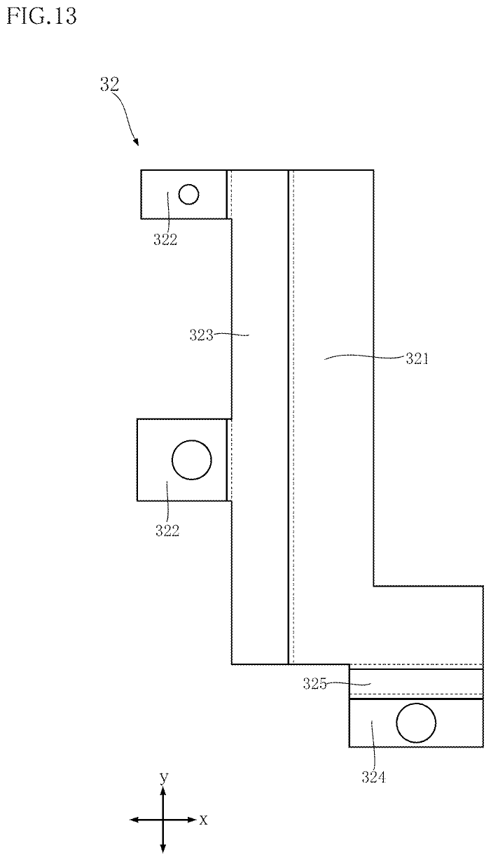

As shown in FIG. 3, the second conductive member 32 is joined to the second electrode 212 of the second element 21B, the upper face electrode 221 of the second diode 22B, and the covered portion 15A of the second input terminal 15. With this, the second electrode 212 of the second element 21B and the upper face electrode 221 of the second diode 22B are electrically connected to, in a state of being electrically connected to each other, the second input terminal 15. The second conductive member 32 contains copper. In the semiconductor device A10, the second conductive member 32 is a metal clip. As shown in FIG. 13, the second conductive member 32 includes a main body portion 321, a plurality of third junction portions 322, a third connection portion 323, a fourth junction portion 324, and a fourth connection portion 325.

As shown in FIG. 13, the main body portion 321 is a main portion of the second conductive member 32. The main body portion 321 extends along the second direction y. As shown in FIGS. 7, 8, and 10, the main body portion 311 is in parallel with the second obverse face 121 of the second conductive plate 12. The main body portion 321 is located apart from the first obverse face 111 of the first conductive plate 11 and the second obverse face 121 relative to the main body portion 311 of the first conductive member 31, and extends above the second junction portion 314 of the first conductive member 31.

As shown in FIGS. 3, 7, and 8, the plurality of third junction portions 322 are individually and electrically joined to the second electrode 212 of the second element 21B and the upper face electrode 221 of the second diode 22B. The plurality of third junction portions 322 respectively opposes the second electrode 212 of the second element 21B and the upper face electrode 221 of the second diode 22B.

As shown in FIGS. 8 and 13, the third connection portion 323 connects the main body portion 321 and the plurality of third junction portions 322. As shown in FIG. 8, the third connection portion 323 is inclined, viewed along the second direction y, in a direction away from the second obverse face 121 of the second conductive plate 12 while extending from the plurality of third junction portions 322 toward the main body portion 321.

As shown in FIGS. 3, 10, and 11, the fourth junction portion 324 is electrically joined to the covered portion 15A of the second input terminal 15. The fourth junction portion 324 opposes the covered portion 15A.

As shown in FIG. 10, the fourth connection portion 325 connects the main body portion 321 and the fourth junction portion 324. The fourth connection portion 325 is inclined, viewed along the first direction x, in a direction away from the second obverse face 121 of the second conductive plate 12 while extending from the fourth junction portion 324 toward the main body portion 321.

In FIGS. 7 and 8, the plurality of third junction layers 35 each include a portion located between the second electrode 212 of the second element 21B or the upper face electrode 221 of the second diode 22B and opposing one of the plurality of third junction portions 322 of the second conductive member 32. The plurality of third junction layers 35 have conductivity. The plurality of third junction layers 35 are made of lead-free solder, for example. In other cases, the plurality of third junction layers 35 may be made of lead solder. The plurality of third junction layers 35 individually and electrically join the plurality of third junction portions 322 to the second electrode 212 of the second element 21B and the upper face electrode 221 of the second diode 22B. Therefore, the second conductive member 32 is electrically joined to the second electrode 212 of the second element 21B and the upper face electrode 221 of the second diode 22B by the plurality of third junction layers 35.

As shown in FIGS. 10 and 11, the fourth junction layer 36 includes a portion located between the covered portion 15A of the second input terminal 15 and the opposing fourth junction portion 324 of the second conductive member 32. The fourth junction layer 36 has conductivity. The fourth junction layer 36 is made of lead-free solder, for example. In other cases, the fourth junction layer 36 may be made of lead solder. The fourth junction layer 36 electrically joins the fourth junction portion 324 and the covered portion 15A. Therefore, the second conductive member 32 is electrically joined to the covered portion 15A by the fourth junction layer 36.

As shown in FIGS. 3 and 14, the pair of gate wires 41 are individually and electrically join the third electrodes 213 of the pair of switching elements 21 to the covered portion 161A of the first gate terminal 161 and the covered portion 162A of the second gate terminal 162. With this, the first gate terminal 161 is electrically connected to the third electrode 213 of the first element 21A. The second gate terminal 162 is electrically connected to the third electrode 213 of the second element 21B. The pair of gate wires 41 each contain gold. In other cases, the pair of gate wires 41 may each contain copper or aluminum (Al).

As shown in FIGS. 3 and 14, the pair of detection wires 42 are individually and electrically join the second electrodes 212 of the pair of switching elements 21 to the covered portion 171A of the first detection terminal 171 and the covered portion 172A of the second detection terminal 172. With this, the first detection terminal 171 is electrically connected to the second electrode 212 of the first element 21A. The second detection terminal 172 is electrically connected to the second electrode 212 of the second element 21B. The pair of detection wires 42 each contain gold. In other cases, the pair of detection wires 42 may each contain copper or aluminum.

As shown in FIGS. 3, 7 to 10, the sealing resin 50 covers the pair of switching elements 21, the pair of protection elements 22, the first conductive member 31, and the second conductive member 32, and portions of the first conductive plate 11 and the second conductive plate 12. The sealing resin 50 has an electric insulation property. The sealing resin 50 is made of a material containing a black epoxy resin, for example. The sealing resin 50 includes a top face 51, a bottom face 52, a pair of first side faces 53, a pair of second side faces 54, a plurality of recesses 55, and a groove 56.

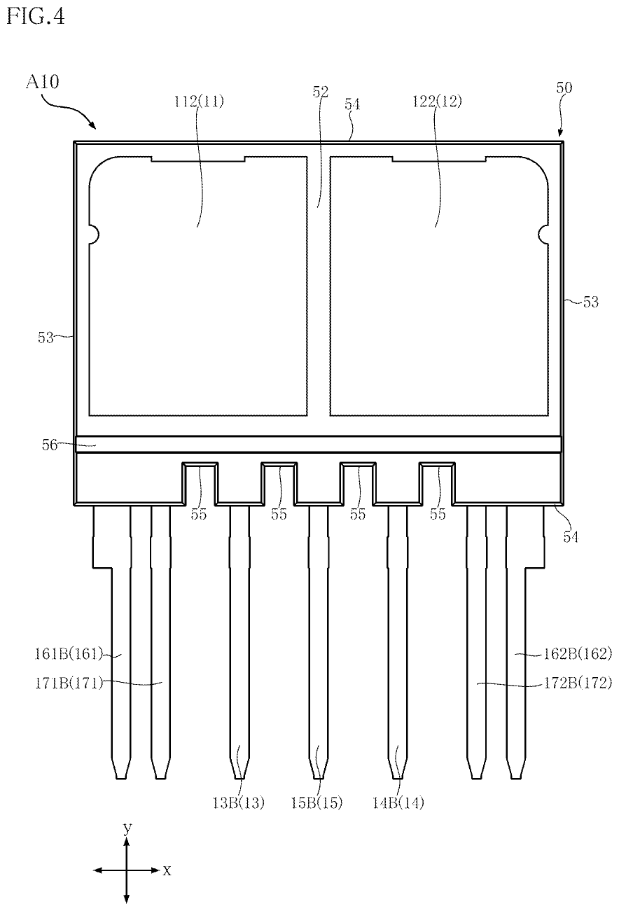

As shown in FIGS. 7 to 10, the top face 51 faces, in the thickness direction z, in the same direction as the first obverse face 111 of the first conductive plate 11. As shown in FIGS. 7 to 10, the bottom face 52 faces, in the thickness direction z, in the direction opposite to that of the top face 51. As shown in FIG. 4, a first reverse face 112 of the first conductive plate 11 and a second reverse face 122 of the second conductive plate 12 are exposed from the bottom face 52.

As shown in FIGS. 2, 4, and 6, the pair of first side faces 53 are located apart from each other in the first direction x. The pair of first side faces 53 are each connected to the top face 51 and the bottom face 52.

As shown in FIGS. 2, 4, and 5, the pair of second side faces 54 are located apart from each other in the second direction y. The pair of second side faces 54 are each connected to the top face 51 and the bottom face 52. As shown in FIG. 5, the exposed portion 13B of the first input terminal 13, the exposed portion 14B of the output terminal 14, and the exposed portion 15B of the second input terminal 15 are exposed from one of the pair of second side faces 54. Moreover, the exposed portion 161B of the first gate terminal 161, the exposed portion 162B of the second gate terminal 162, the exposed portion 171B of the first detection terminal 171, and the exposed portion 172B of the second detection terminal 172 are exposed from this second side face 54.

As shown in FIGS. 2, 4, and 5, the plurality of recesses 55 are recessed, in the second direction y, from the second side face 54, of the pair of second side faces 54, from which the exposed portion 13B of the first input terminal 13 and the like are exposed, and extend from the top face 51 to the bottom face 52, in the thickness direction z. The plurality of recesses 55 are individually located, in the first direction x, between the first input terminal 13 and the first detection terminal 171, between the first input terminal 13 and the second input terminal 15, between the output terminal 14 and the second input terminal 15, and between the output terminal 14 and the second detection terminal 172. As a result of providing the plurality of recesses 55, the creepage distance of the sealing resin 50 between any two of the first input terminal 13, the output terminal 14, the second input terminal 15, the first detection terminal 171, and the second detection terminal 172 is secured to be longer. Moreover, the creepage distance of the sealing resin 50 between any of the first gate terminal 161 and the second gate terminal 162 and any of the first input terminal 13, the output terminal 14, and the second input terminal 15 is secured to be longer. This fact is favorable for improving the dielectric strength voltage of the semiconductor device A10.

As shown in FIGS. 4, 6, and 9 to 11, the groove 56 is recessed from the bottom face 52, in the thickness direction z, and extends along the first direction x. The two ends of the groove 56 in the first direction x are connected to the pair of first side faces 53. As a result of providing the groove 56, the creepage distances of the sealing resin 50 from the first conductive plate 11 and the second conductive plate 12 to the first input terminal 13, the output terminal 14, the second input terminal 15, the first gate terminal 161, the second gate terminal 162, the first detection terminal 171, and the second detection terminal 172 are secured to be longer. This fact is favorable for improving the dielectric strength voltage of the semiconductor device A10.

Next, the effects of the semiconductor device A10 will be described.

The semiconductor device A10 includes the conductive member (first conductive member 31) that is electrically joined to the electrodes (the second electrode 212 of the first element 21A and the upper face electrode 221 of the first diode 22A, in the semiconductor device A10) of the plurality of semiconductor elements 20 and the second obverse face 121 of the second conductive plate 12. The conductive member includes the main body portion 311, the plurality of first junction portions 312, the first connection portion 313, the second junction portion 314, and the third junction layer 35. The plurality of first junction portions 312 are individually and electrically joined to the electrodes of the plurality of semiconductor elements 20. The second junction portion 314 is electrically joined to the second obverse face 121. Accordingly, joining of these portions of the conductive member is collectively performed, and therefore the conductive member can be individually and electrically joined to the electrodes of the plurality of semiconductor elements 20 in a shorter period and efficiently. Therefore, according to the semiconductor device A10, the manufacturing efficiency of the semiconductor device A10 can be improved while making it possible to handle larger current.

The plurality of first junction portions 312 each include the overlapping area 312B that overlaps, as viewed along the thickness direction z, with one of the electrodes of the plurality of semiconductor elements 20. The area of the overlapping area 312B viewed along the thickness direction z is 70% or more of each of the areas of the electrodes of the plurality of semiconductor elements 20. This fact is favorable for relaxing the concentration of thermal stress acting on the first junction layer 33 and each of the plurality of first junction portions 312, while making it possible to allow a larger current to flow through each of the plurality of semiconductor elements 20.

At least a portion of the main body portion 311 overlaps with the first obverse face 111 of the first conductive plate 11 viewed along the thickness direction z. This fact is favorable for reducing the size of the semiconductor device A10 in the first direction x.

The first connection portion 313 is inclined, viewed along the second direction y, in a direction away from the first obverse face 111 of the first conductive plate 11 while extending from the first junction portion 312 toward the main body portion 311. With this, fillets are likely to be formed in the respective plurality of first junction layers 33, the fillets being located on one side, in the first direction x, of the electrodes of the plurality of semiconductor elements 20. Therefore, the concentration of thermal stress acting on the interface between each of the electrodes of the plurality of semiconductor elements 20 and the first junction layer 33 can be more effectively reduced. In this case, the fillet having a shape in which the size of the acute angle a formed between the first junction portion 312 and the first connection portion 313 viewed along the second direction y being 30° or more and 60° or less is appropriate for relaxing the concentration of thermal stress. In contrast, the case where the acute angle a is less than 30° is not preferable from the viewpoint of preventing the dielectric breakdown of the semiconductor elements 20, because the distance between each of the plurality of semiconductor elements 20 and the conductive member (first conductive member 31) is excessively small. On the other hand, when the acute angle a exceeds 60°, the volume of the fillet formed in one of the plurality of first junction layers 33 is excessively large, and therefore the thermal stress incurring in the first junction layer 33 is likely to be concentrated. This fact is not preferable from the viewpoint of relaxing the concentration of thermal stress in the first junction layer 33.

The thickness t of the first junction portion 312 is twice of the maximum thickness Tₘₐₓ of the first junction layer 33 or less. With this, the concentration of thermal stress acting on the interface between the first junction layer 33 and the first junction portion 312 can be reduced while securing the thermal durability of the first junction layer 33.

The plurality of first junction portions 312 each include the opening 312A that passes through in the thickness direction z. When the first junction portions 312 are electrically joined to the electrodes of the plurality of semiconductor elements 20 by the first junction layers 33, as a result of providing the openings 312A, bubbles included in the melted first junction layers 33 can be discharged to the outside. Moreover, the first junction layers 33 are each in contact with the inner circumferential surface of the first junction portion 312 that defines the opening 312A. With this, a self-alignment effect can be obtained regarding the melted first junction layers 33 such that the first junction portions 312 are positioned to predetermined positions relative to the electrodes of the respective switching elements 21.

The conductive member contain copper. With this, the electric resistance of the conductive member can be reduced relative to a wire containing aluminum. This fact is favorable for allowing a larger current to flow by the switching elements 21.

The first conductive plate 11 contains copper. Moreover, the thickness T1 of the first conductive plate 11 is larger than the maximum thickness tₘₐₓ of the conductive member. With this, the thermal conduction efficiency in the in-plane direction (first direction x and second direction y) of the first obverse face 111 can be improved while improving the thermal conductivity of the first conductive plate 11. This fact contributes to improving the heat dissipation property of the semiconductor device A10.

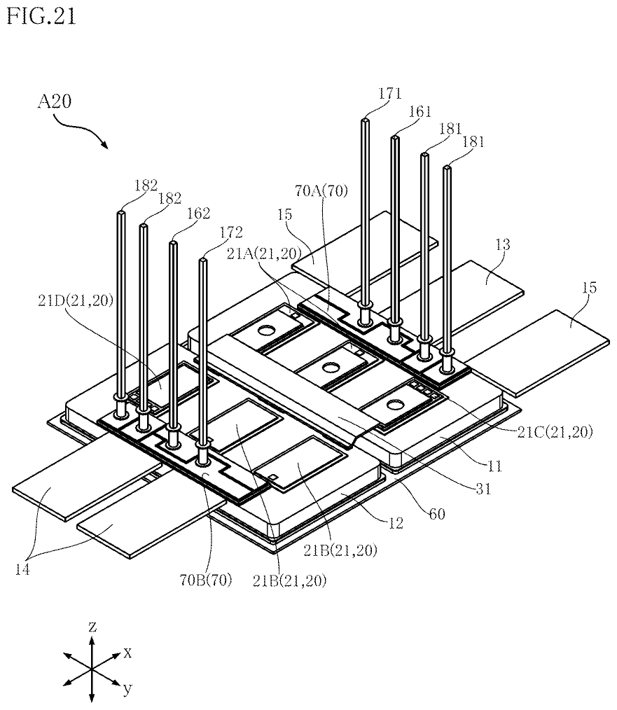

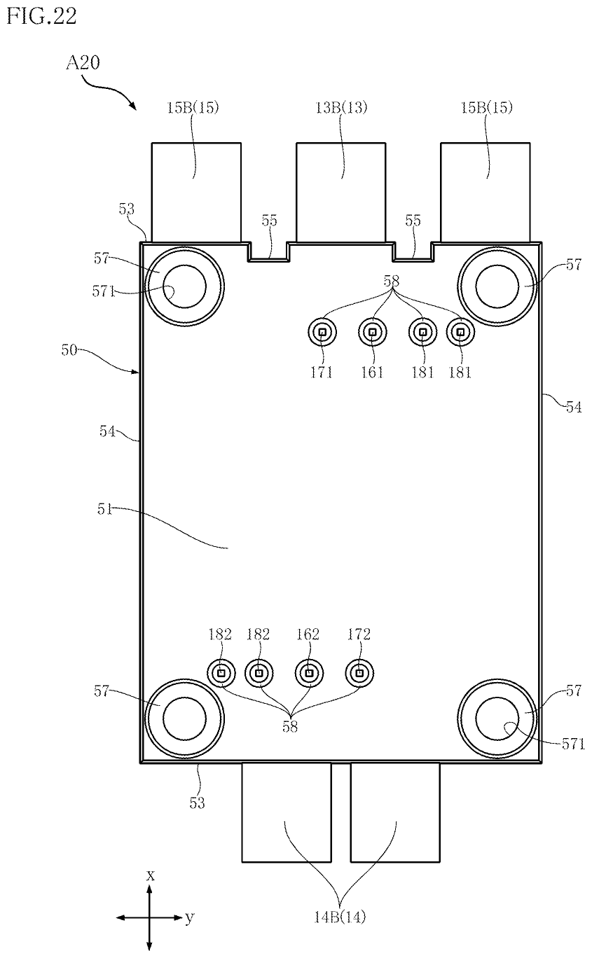

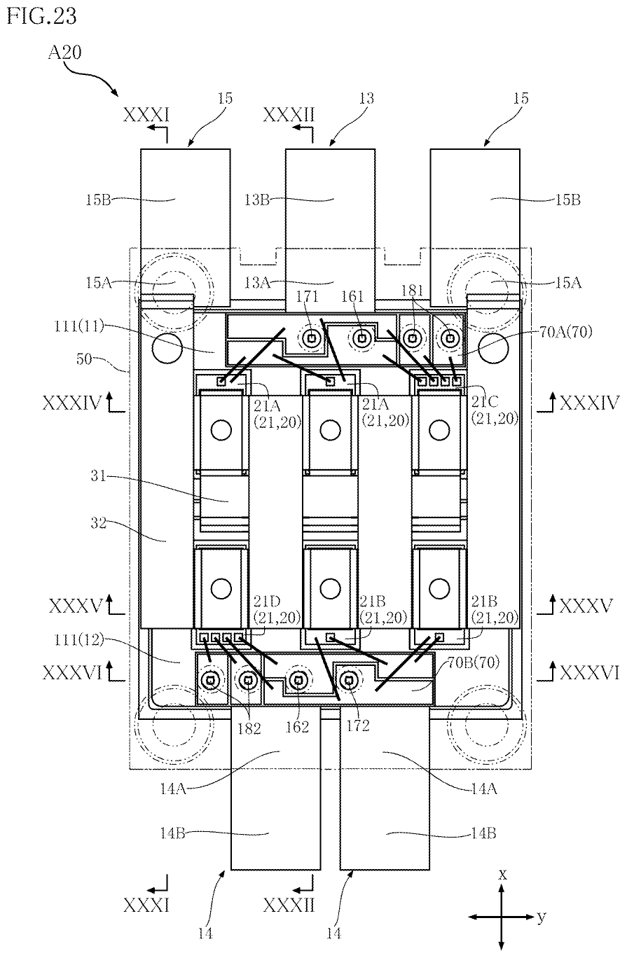

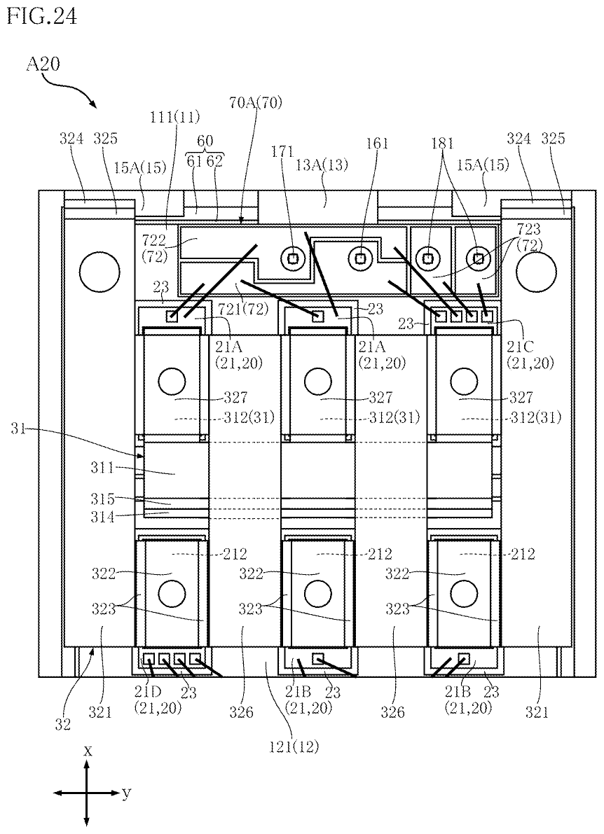

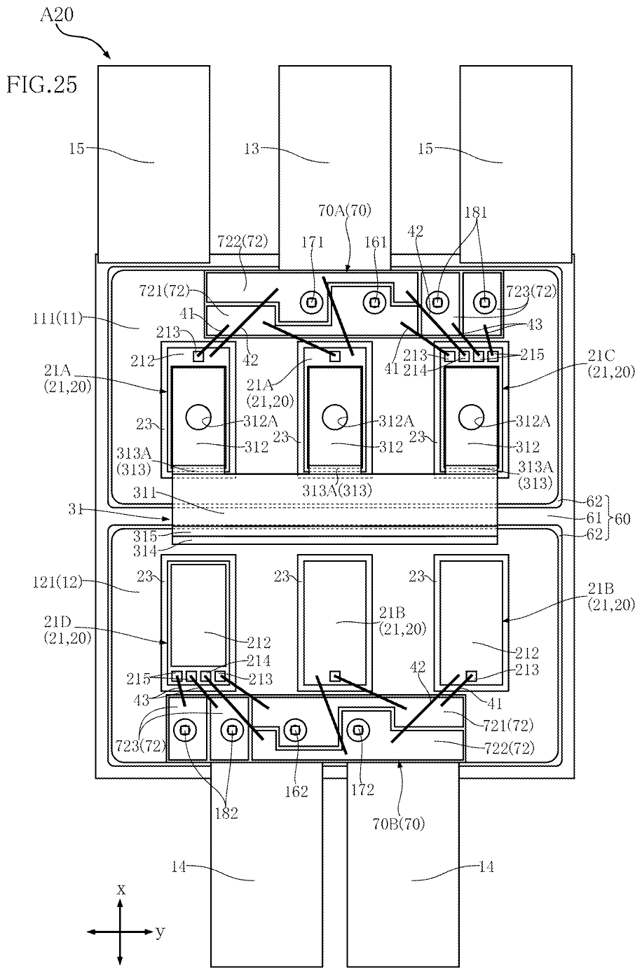

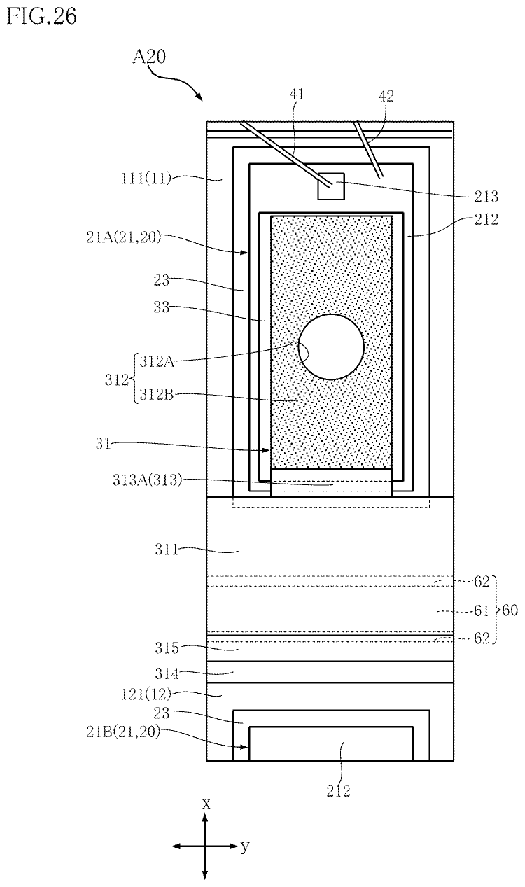

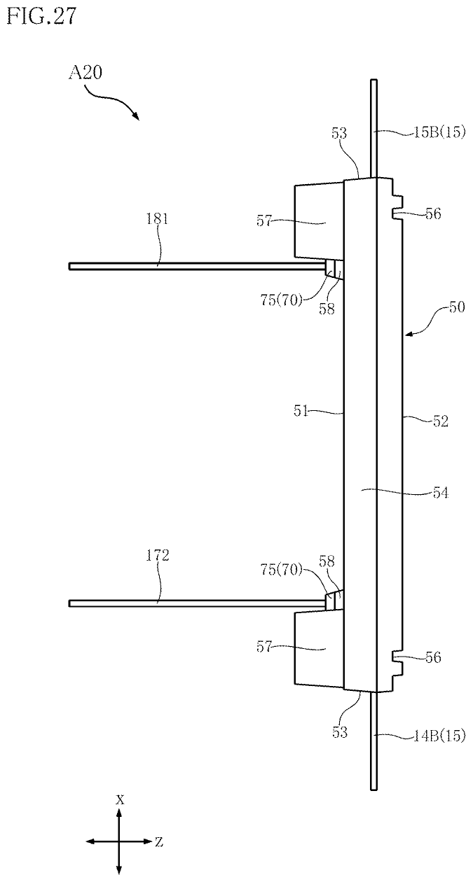

A semiconductor device A20 according to a second embodiment of the present disclosure will be described based on FIGS. 19 to 37. In these drawings, the same or similar constituent elements as those of the semiconductor device A10 described above are assigned the same reference numerals, and redundant descriptions are omitted. Here, in FIG. 20, illustration of the sealing resin 50 is omitted in order to facilitate understanding. Illustration of the sealing resin 50 and the second conductive member 32 are omitted in FIGS. 21 and 25 in order to facilitate understanding. In FIG. 23, the sealing resin 50 is made transparent in order to facilitate understanding. In FIG. 23, the sealing resin 50 that is made transparent is shown by imaginary lines.

In contrast to the semiconductor device A10, the semiconductor device A20 further includes a support substrate 60, a pair of first diode terminals 181, a pair of second diode terminals 182, a pair of control interconnects 70, and a plurality of diode wires 43.

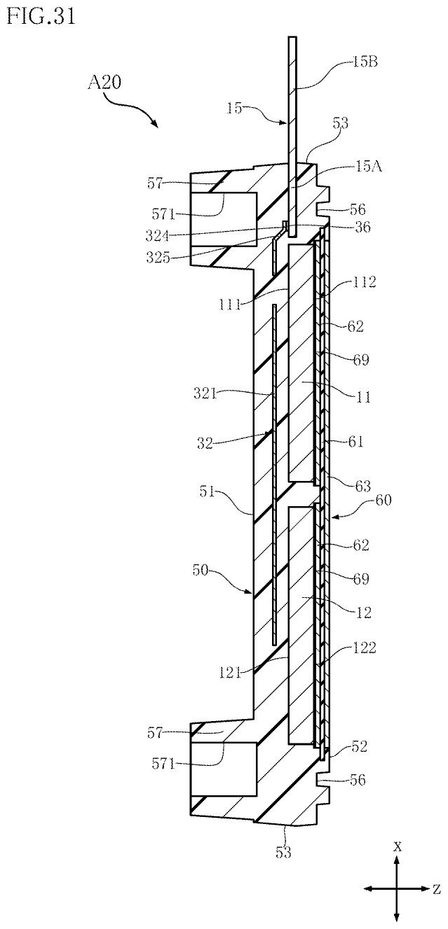

As shown in FIGS. 20 and 21, the support substrate 60 supports the first conductive plate 11 and the second conductive plate 12. In the semiconductor device A20, the support substrate 60 is constituted by a DBC (Direct Bonded Copper) substrate. As shown in FIGS. 31 to 36, the support substrate 60 includes an insulating layer 61, a pair of first metal layers 62, and a second metal layer 63. The support substrate 60 is covered by the sealing resin 50 except for a portion of the second metal layer 63.

As shown in FIGS. 31 to 36, the insulating layer 61 includes a portion that is present between the pair of first metal layers 62 and the second metal layer 63 in the thickness direction z. The insulating layer 61 is made of a material having a relatively high thermal conductivity. The insulating layer 61 is made of ceramics containing aluminum nitride (AlN), for example. The insulating layer 61 may also be constituted by an insulating resin sheet, other than ceramics.

As shown in FIGS. 31 to 36, the pair of first metal layers 62 are located on one side of the insulating layer 61 in the thickness direction z. The pair of first metal layers 62 are located apart from each other in the first direction x. The pair of first metal layers 62 each contain copper. The first reverse face 112 of the first conductive plate 11 is joined to one of the pair of first metal layers 62 by a junction layer 69. The second reverse face 122 of the second conductive plate 12 is joined to the other of the pair of first metal layers 62 by the junction layer 69. With this, a configuration is achieved in which the first conductive plate 11 and the second conductive plate 12 are supported by the support substrate 60, in the semiconductor device A20. The junction layer 69 is made of brazing filler metal containing silver (Ag), for example. As shown in FIG. 25, the pair of first metal layers 62 are located inward of the peripheral edge of the insulating layer 61 viewed along the thickness direction z.

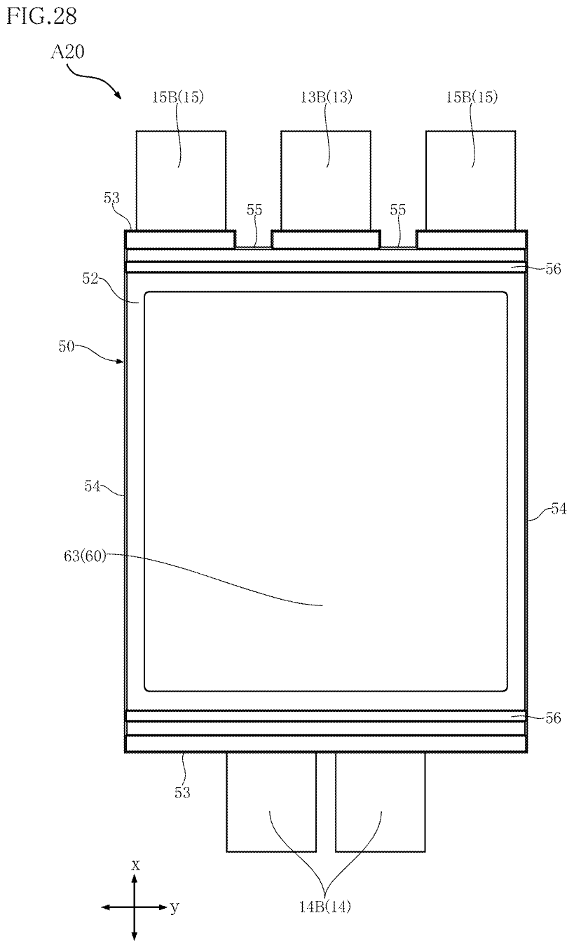

As shown in FIGS. 31 to 36, the second metal layer 63 is located on the other side of the insulating layer 61 in the thickness direction z. As shown in FIG. 28, the surface of the second metal layer 63 (face facing in the thickness direction z) is exposed from the bottom face 52 of the sealing resin 50. The surface is to be joined to a heat sink (not illustrated). The second metal layer 63 contains copper. The peripheral edge of the second metal layer 63 is located inward of the peripheral edge of the insulating layer 61 viewed along the thickness direction z.

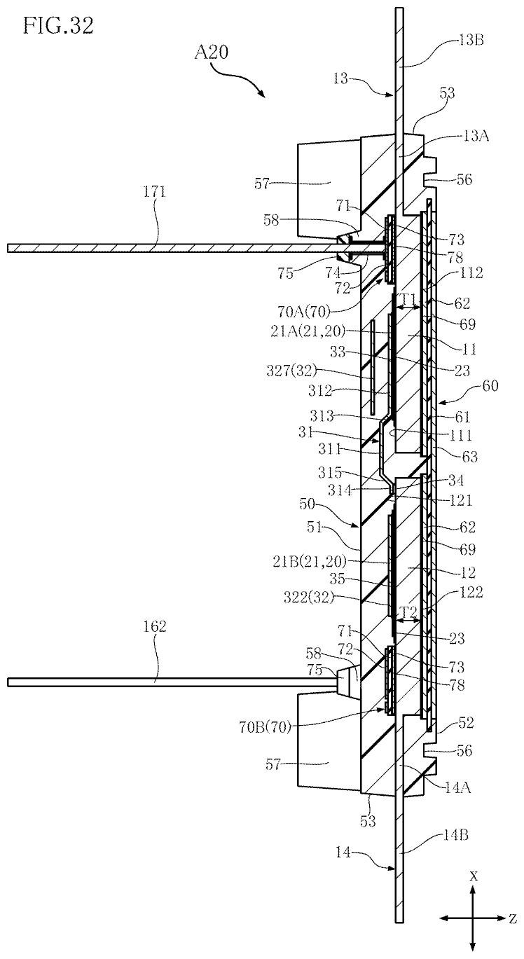

As shown in FIGS. 23 and 32, the first input terminal 13 is located on one side in the first direction x, and is integrated to the first conductive plate 11. The first input terminal 13 extends from the first conductive plate 11 along the first direction x. The thickness of the first input terminal 13 is smaller than the thickness T1 of the first conductive plate 11. As shown in FIGS. 23 and 32, the output terminal 14 is located on the other side in the first direction x, and is integrated to the second conductive plate 12. In the semiconductor device A20, the output terminal 14 includes a pair of areas that are located apart from each other in the second direction y. The pair of areas each extend from the second conductive plate 12 along the first direction x. The thickness of each of the areas is smaller than the thickness T2 of the second conductive plate 12. As shown in FIGS. 23 and 31, the second input terminal 15 is located on one side in the first direction x. The second input terminal 15 is located apart from the first conductive plate 11 in the first direction x. In the semiconductor device A20, the second input terminal 15 includes a pair of areas that are located apart from each other in the second direction y. The pair of areas are located on two sides of the first input terminal 13 in the second direction y. The pair of areas each extend along the first direction x.

In the semiconductor device A20, the plurality of semiconductor elements 20 includes a plurality of switching elements 21. As shown in FIGS. 23 and 25, the plurality of switching elements 21 includes a pair of first elements 21A, a pair of second elements 21B, a third element 21C, and a fourth element 21D. Among these, the configurations of the third element 21C and the fourth element 21D are each different from each of the configurations of the pair of first elements 21A and the pair of second elements 21B. The configurations of the third element 21C and the fourth element 21D are the same. The third element 21C is joined to the first obverse face 111 of the first conductive plate 11. The fourth element 21D is joined to the second obverse face 121 of the second conductive plate 12.

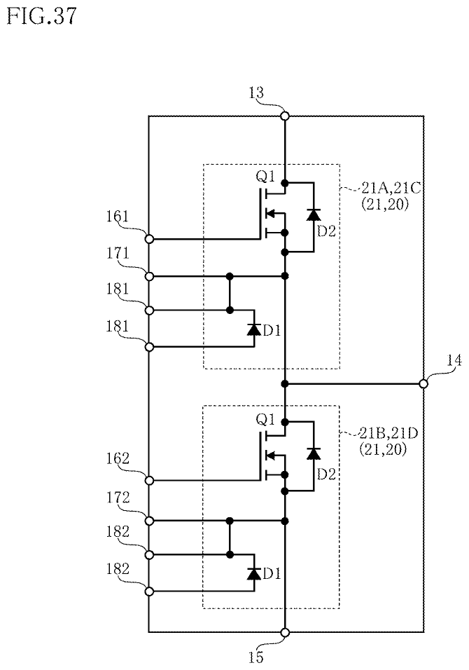

The plurality of switching elements 21 each include a switching function unit Q1 and a flyback diode D2 shown in FIG. 37. Out of the plurality of switching elements 21, the third element 21C and the fourth element 21D each further include a diode function part D1 shown in FIG. 37, in addition to the switching function unit Q1 and the flyback diode D2. The third element 21C and the fourth element 21D each further include a fourth electrode 214 and a pair of fifth electrodes 215, in addition to the first electrode 211, the second electrode 212, and the third electrode 213. In each of the third element 21C and the fourth element 21D, a current that is the same as the current flowing through the second electrode 212 flows through the fourth electrode 214. In each of the third element 21C and the fourth element 21D, the pair of fifth electrodes 215 are electrically connected to the diode function part Dl.

As shown in FIG. 37, a half-bridge type switching circuit is constituted in the semiconductor device A20. The pair of first elements 21A and the third element 21C constitute an upper arm circuit. In the upper arm circuit, the pair of first elements 21A and the third element 21C are connected in parallel. The pair of second elements 21B and the fourth element 21D constitute a lower arm circuit. In the lower arm circuit, the pair of second elements 21B and the fourth element 21D are connected in parallel.

As shown in FIGS. 23 and 25, the pair of first elements 21A and the third element 21C are arranged along the second direction y on the first obverse face 111 of the first conductive plate 11. The pair of second elements 21B and the fourth element 21D are arranged along the second direction y on the second obverse face 121 of the second conductive plate 12. As described above, in the semiconductor device A20 as well, the plurality of semiconductor elements 20 are arranged along the second direction y.

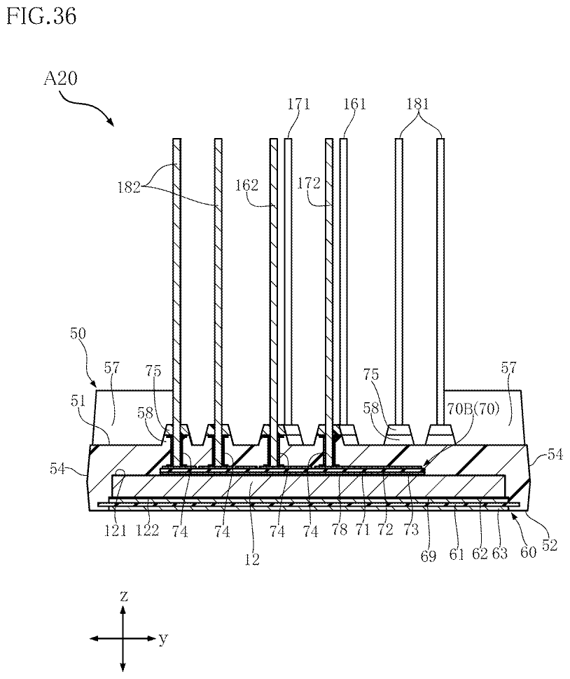

The pair of control interconnects 70 constitute a portion of the conductive paths between the first gate terminal 161, the second gate terminal 162, the first detection terminal 171, the second detection terminal 172, the pair of first diode terminals 181, and the pair of second diode terminals 182 and the plurality of switching elements 21. As shown in FIGS. 23 to 25, the pair of control interconnects 70 includes a first interconnect 70A and a second interconnect 70B. The first interconnect 70A is located between elements (the pair of first elements 21A and the third element 21C) and terminals (the first input terminal 13 and the second input terminal 15), in the first direction x. The first interconnect 70A is joined to the first obverse face 111 of the first conductive plate 11. The second interconnect 70B is located between elements (the pair of second elements 21B and the fourth element 21D) and the output terminal 14, in the first direction x. The second interconnect 70B is joined to the second obverse face 121 of the second conductive plate 12. As shown in FIGS. 32 and 36, the pair of control interconnects 70 each include an insulating layer 71, a plurality of interconnect layers 72, a metal layer 73, a plurality of holders 74, and a plurality of covering layers 75. The control interconnects 70 are covered by the sealing resin 50 except for portions of the plurality of holders 74 and the plurality of covering layers 75.

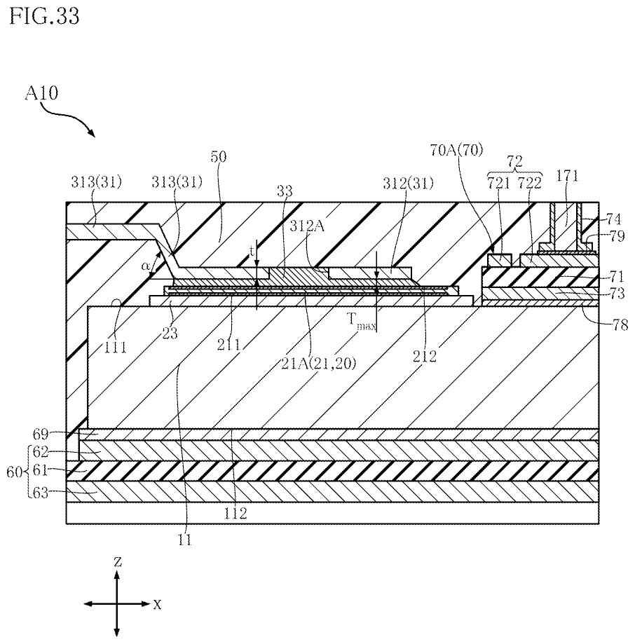

As shown in FIG. 33, the insulating layer 71 includes a portion that is present between the plurality of interconnect layers 72 and the metal layer 73 in the thickness direction z. The insulating layer 71 is made of ceramics, for example. The insulating layer 71 may also be constituted by an insulating resin sheet, other than ceramics.

As shown in FIG. 33, the plurality of interconnect layers 72 are located on one side of the insulating layer 71 in the thickness direction z. The plurality of interconnect layers 72 each contain copper. As shown in FIG. 25, the plurality of interconnect layers 72 includes a first interconnect layer 721, a second interconnect layer 722, and a pair of third interconnect layers 723. The areas of the pair of third interconnect layers 723, viewed along the thickness direction z, are each smaller than the area of the first interconnect layer 721 and the area of the second interconnect layer 722.

As shown in FIG. 33, the metal layer 73 is located on the other side of the insulating layer 71 in the thickness direction z. The metal layer 73 contains copper. The metal layer 73 of the first interconnect 70A is joined to the first obverse face 111 of the first conductive plate 11 by the junction layer 78. The metal layer 73 of the second interconnect 70B is joined to the second obverse face 121 of the second conductive plate 12 by the junction layer 78. The junction layer 78 is made of material selected without considering conductivity. The junction layer 78 is made of lead-free solder, for example.

As shown in FIG. 33, the plurality of holders 74 are individually and electrically joined to the plurality of interconnect layers 72 by the holder junction layers 79. The plurality of holders 74 are made of conductive material such as metal. The plurality of holders 74 are each tubular extending along the thickness direction z. The lower end, in the thickness direction z, of each of the plurality of holders 74 is electrically joined to one of the plurality of interconnect layers 72. The upper end, in the thickness direction z, of each of the plurality of holders 74 is exposed from the sealing resin 50. The holder junction layers 79 have conductivity. The holder junction layers 79 are made of lead-free solder, for example.

As shown in FIGS. 32 and 36, the plurality of covering layers 75 individually covers the upper ends, in the thickness direction z, of the plurality of holders 74. The plurality of covering layers 75 are arranged so as to be individually in contact with later-described second protrusions 58 of the sealing resin 50. The plurality of covering layers 75 each have an electric insulation property. The plurality of covering layers 75 are each made of material containing synthetic resin.

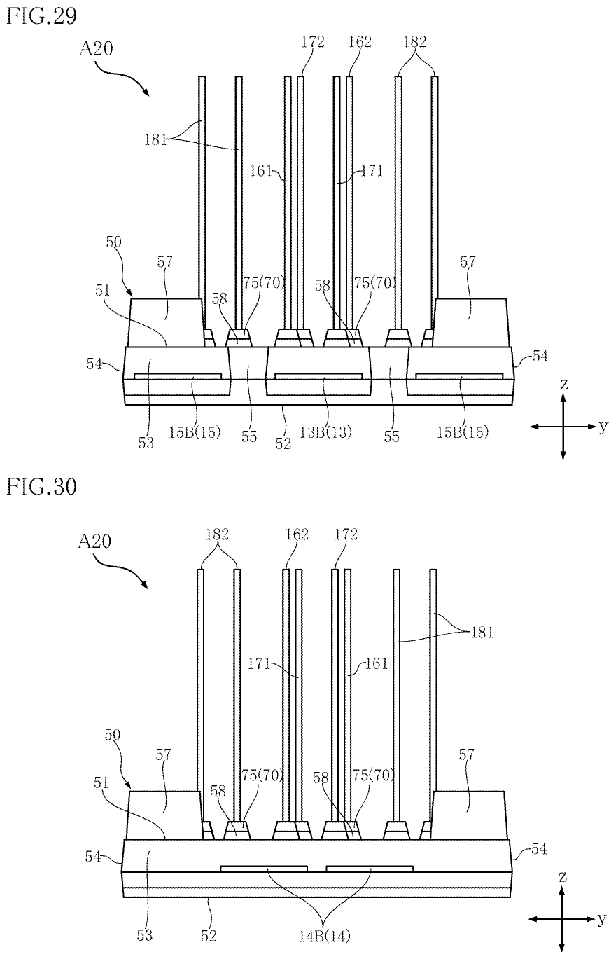

As shown in FIGS. 19 to 21, in the semiconductor device A20, the first gate terminal 161, the second gate terminal 162, the first detection terminal 171, the second detection terminal 172, the pair of first diode terminals 181, and the pair of second diode terminals 182 are each formed by a metal pin that extends in the thickness direction z. These terminals are individually press-fitted to the plurality of holders 74 of the pair of control interconnects 70. With this, these terminals are individually supported by the plurality of holders 74. Moreover, as shown in FIGS. 29, 30, and 36, a portion of each of these terminals is covered by one of the plurality of covering layers 75 of the control interconnect 70.

As shown in FIG. 24, the first gate terminal 161 is press-fitted to the holder 74, of the plurality of holders 74, that is joined to the first interconnect layer 721 of the first interconnect 70A. With this, the first gate terminal 161 is supported by the holder 74, and is electrically connected to the first interconnect layer 721 of the first interconnect 70A.

As shown in FIGS. 24 and 33, the first detection terminal 171 is press-fitted to the holder 74, of the plurality of holders 74, that is joined to the second interconnect layer 722 of the first interconnect 70A. With this, the first detection terminal 171 is supported by the holder 74, and is electrically connected to the second interconnect layer 722 of the first interconnect 70A.

As shown in FIG. 24, the pair of first diode terminals 181 are individually press-fitted to the pair of holders 74, of the plurality of holders 74, that are joined to the pair of third interconnect layers 723 of the first interconnect 70A. With this, the pair of first diode terminals 181 are supported by the pair of holders 74, and are individually electrically connected to the pair of third interconnect layers 723 of the first interconnect 70A.

As shown in FIGS. 25 and 36, the second gate terminal 162 is press-fitted to the holder 74, of the plurality of holders 74, that is joined to the first interconnect layer 721 of the second interconnect 70B. With this, the second gate terminal 162 is supported by the holder 74, and is electrically connected to the first interconnect layer 721 of the second interconnect 70B.

As shown in FIGS. 25 and 36, the second detection terminal 172 is press-fitted to the holder 74, of the plurality of holders 74, that is joined to the second interconnect layer 722 of the second interconnect 70B. With this, the second detection terminal 172 is supported by the holder 74, and is electrically connected to the second interconnect layer 722 of the second interconnect 70B.

As shown in FIGS. 25 and 36, the pair of second diode terminals 182 are individually press-fitted to the pair of holders 74, of the plurality of holders 74, that are joined to the pair of third interconnect layers 723 of the second interconnect 70B. With this, the pair of second diode terminals 182 are supported by the pair of holders 74, and are individually and electrically connected to the pair of third interconnect layers 723 of the second interconnect 70B.

As shown in FIG. 25, the plurality of gate wires 41 are individually and electrically joined to the third electrodes 213 of the plurality of switching elements 21, the first interconnect layer 721 of the first interconnect 70A, and the first interconnect layer 721 of the second interconnect 70B. With this, the first gate terminal 161 is electrically connected to the third electrodes 213 of the pair of first elements 21A and the third electrode 213 of the third element 21C. The second gate terminal 162 is electrically connected to the third electrodes 213 of the pair of second elements 21B and the third electrode 213 of the fourth element 21D.

As shown in FIG. 25, the plurality of detection wires 42 are individually and electrically joined to the second electrodes 212 of the pair of first elements 21A, the second electrodes 212 of the pair of second elements 21B, the fourth electrode 214 of the third element 21C, the fourth electrode 214 of the fourth element 21D, the second interconnect layer 722 of the first interconnect 70A, and the second interconnect layer 722 of the second interconnect 70B. With this, the first detection terminal 171 is electrically connected to the second electrodes 212 of the pair of first elements 21A and the fourth electrode 214 of the third element 21C. The second detection terminal 172 is electrically connected to the second electrodes 212 of the pair of second elements 21B and the fourth electrode 214 of the fourth element 21D.

As shown in FIG. 25, the plurality of diode wires 43 are individually and electrically joined to the pair of fifth electrodes 215 of the third element 21C, the pair of fifth electrodes 215 of the fourth element 21D, the pair of third interconnect layers 723 of the first interconnect 70A, and the pair of third interconnect layers 723 of the second interconnect 70B. With this, the pair of first diode terminals 181 are individually and electrically connected to the pair of fifth electrodes 215 of the third element 21C. The pair of second diode terminals 182 are individually and electrically connected to the pair of fifth electrodes 215 of the fourth element 21D. The plurality of diode wires 43 each contain gold. In other cases, the plurality of diode wires 43 may each contain copper or aluminum.

As shown in FIG. 25, the first conductive member 31 is electrically joined to the second electrodes 212 of the pair of first elements 21A, the second electrode 212 of the third element 21C, and the second obverse face 121 of the second conductive plate 12. With this, the second electrodes 212 of the pair of first elements 21A and the second electrode 212 of the third element 21C are electrically connected to the second conductive plate 12 in a state of being electrically connected to each other.

As shown in FIGS. 25, 26, and 33, in the semiconductor device A20, the plurality of first junction portions 312 are individually and electrically joined to the second electrodes 212 of the pair of first elements 21A and the second electrode 212 of the third element 21C. The plurality of first junction portions 312 each oppose either the second electrodes 212 of the pair of first elements 21A or the second electrode 212 of the third element 21C.

As shown in FIG. 25, in the semiconductor device A20, the first connection portion 313 of the first conductive member 31 includes a plurality of connection areas 313A (three connection areas 313A in FIG. 25). The plurality of connection areas 313A are located apart from each other in the second direction y. The plurality of connection areas 313A are individually connected to the plurality of first junction portions 312 of the first conductive member 31. As shown in FIG. 32, the plurality of connection areas 313A each incline, viewed along the second direction y, so as to separate from the first obverse face 111 of the first conductive plate 11 toward the main body portion 311 of the first conductive member 31 from corresponding one of the plurality of first junction portions 312. The size of acute angle a (refer to FIG. 33), viewed along the second direction y, that is formed between each of the plurality of first junction portions 312 and corresponding one of the plurality of connection areas 313A connected thereto is 30° or more and 60° or less.

As shown in FIG. 24, the second conductive member 32 is joined to the second electrode 212 of the pair of second elements 21B, the second electrode 212 of the fourth element 21D, and the covered portion 15A of the second input terminal 15. With this, the second electrode 212 of the pair of second elements 21B and the second electrode 212 of the fourth element 21D are electrically connected to the second input terminal 15 in a state of being electrically connected to each other. As shown in FIG. 24, in the semiconductor device A20, the second conductive member 32 includes a pair of main body portions 321, a plurality of third junction portions 322, a plurality of third connection portions 323, a pair of fourth junction portions 324, a pair of fourth connection portions 325, a pair of intermediate portions 326, and a plurality of transverse beam portions 327.

As shown in FIG. 24, the pair of main body portions 321 are located apart from each other in the second direction y. The pair of main body portions 321 each extend along the first direction x. As shown in FIG. 31, the pair of main body portions 321 are each in parallel with the first obverse face 111 of the first conductive plate 11 and the second obverse face 121 of the second conductive plate 12. The pair of main body portions 321 are located apart from the first obverse face 111 and the second obverse face 121 relative to the main body portion 311 of the first conductive member 31.

As shown in FIG. 24, the pair of intermediate portions 326 are located apart from each other in the second direction y, and are located between the pair of main body portions 321 in the second direction y. The pair of intermediate portions 326 each extend along the first direction x. The sizes of the pair of intermediate portions 326 in the first direction x are each smaller than each of the sizes of the pair of main body portions 321 in the first direction x. The pair of second elements 21B are located on two sides, in the second direction y, of one of the pair of intermediate portions 326, viewed along the thickness direction z. One of the pair of second elements 21B and the fourth element 21D are located on two side, in the second direction y, of the other of the pair of intermediate portions 326, viewed along the thickness direction z.

As shown in FIG. 24, the plurality of third junction portions 322 are individually and electrically joined to the second electrode 212 of the pair of second elements 21B and the second electrode 212 of the fourth element 21D. The plurality of third junction portions 322 each oppose either the second electrode 212 of the pair of second elements 21B or the second electrode 212 of the fourth element 21D.

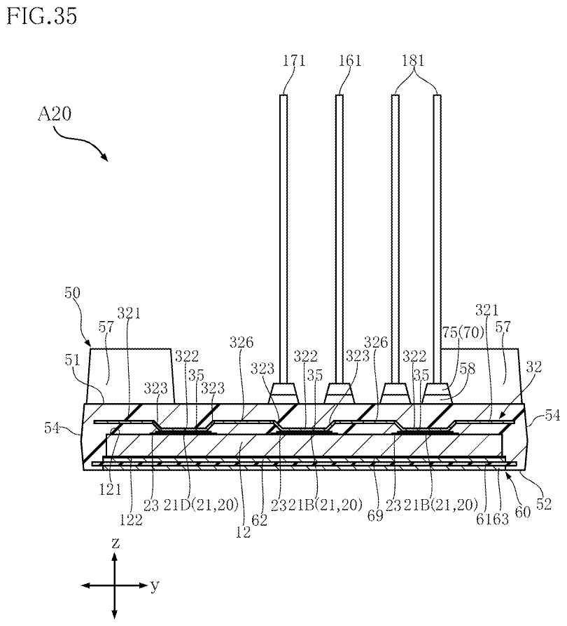

As shown in FIGS. 24 and 35, a pair of the third connection portions 323, of the plurality of third connection portions 323, are connected to two ends, in the second direction y, of one of the plurality of third junction portions 322. A pair of the third connection portions 323 are connected to a pair of intermediate portions 326, or one of the pair of intermediate portions 326 and one of the pair of main body portions 321. The plurality of third connection portions 323 each incline, viewed along the first direction x, so as to separate from the second obverse face 121 of the second conductive plate 12 toward one of the pair of main body portions 321 or one of the pair of intermediate portions 326 from one of the plurality of third junction portions 322.

As shown in FIGS. 24 and 31, the pair of fourth junction portions 324 are individually and electrically joined to a pair of areas of the covered portion 15A of the second input terminal 15. The pair of fourth junction portions 324 each oppose one of the pair of areas of the covered portion 15A.

As shown in FIGS. 24 and 31, the pair of fourth connection portions 325 individually connect between the pair of main body portions 321 and the pair of fourth junction portions 324. The pair of fourth connection portions 325 each incline, viewed along the second direction y, so as to separate from the first obverse face 111 of the first conductive plate 11 toward one of the pair of main body portions 321 from one of the pair of fourth junction portions 324.

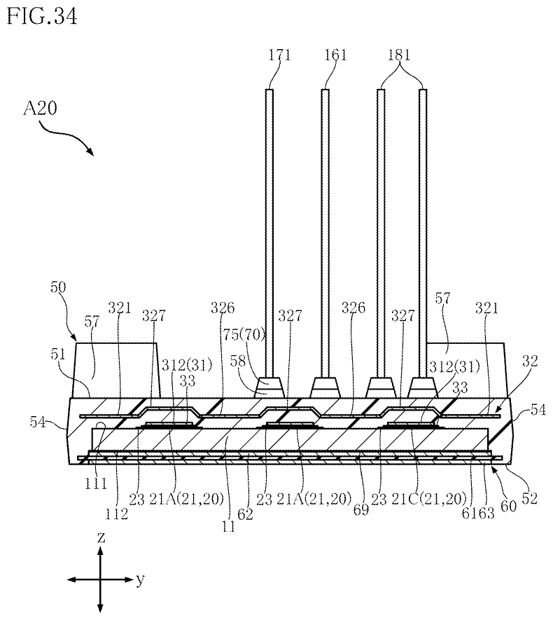

As shown in FIGS. 24 and 34, the plurality of transverse beam portions 327 are arranged along the second direction y. The plurality of transverse beam portions 327 include areas that individually overlap, as viewed along the thickness direction z, with the plurality of first junction portions 312 of the first conductive member 31. The two ends, in the second direction y, of each of the plurality of transverse beam portions 327 are connected to the pair of intermediate portions 326, or one of the pair of intermediate portions 326 and one of the pair of main body portions 321. The plurality of transverse beam portions 327 each protrude, viewed along the first direction x, in a direction, in the thickness direction z, in which the first obverse face 111 of the first conductive plate 11 faces.

As shown in FIGS. 22, and 27 to 30, in the semiconductor device A20, the sealing resin 50 further includes a plurality of first protrusions 57 and a plurality of second protrusions 58, in addition to the top face 51, the bottom face 52, the pair of first side faces 53, the pair of second side faces 54, the plurality of recesses 55, and the groove 56.

As shown in FIGS. 27, 29, and 30, the plurality of first protrusions 57 protrude from the top face 51, in the thickness direction z. As shown in FIG. 22, the plurality of first protrusions 57 are arranged at four corners of the sealing resin 50, viewed along the thickness direction z. The external form of each of the plurality of first protrusions 57 is a truncated cone shape. As shown in FIGS. 22 and 31, the plurality of first protrusions 57 each include an attachment hole 571. The attachment holes 571 of the plurality of first protrusions 57 do not pass through the own attachment holes 571 in the thickness direction z. The plurality of first protrusions 57 are used for mounting a driver module on the semiconductor device A20. The driver module is for driving and controlling the semiconductor device A20.

As shown in FIGS. 27, 29, and 30, the plurality of second protrusions 58 protrude from the top face 51 in the thickness direction z. As shown in FIG. 22, the plurality of second protrusions 58 are individually arranged with respect to the first gate terminal 161, the second gate terminal 162, the first detection terminal 171, the second detection terminal 172, the pair of first diode terminals 181, and the pair of second diode terminals 182. As shown in FIGS. 32 and 36, the plurality of second protrusions 58 respectively cover portions of the respective plurality of holders 74 of the pair of control interconnects 70. The upper ends, in the thickness direction z, of the respective plurality of holders 74 are exposed from the respective plurality of second protrusions 58.

As shown in FIGS. 29 and 30, in the semiconductor device A20, the exposed portion 13B of the first input terminal 13 and the exposed portion 15B of the second input terminal 15 are exposed from one of the pair of first side faces 53. The exposed portion 14B of the output terminal 14 is exposed from the other of the pair of first side faces 53.

As shown in FIGS. 22, 28, and 29, in the semiconductor device A20, the plurality of recesses 55 are recessed, in the first direction x, from the first side face 53, of the pair of first side faces 53, from which the exposed portion 13B of the first input terminal 13 and the exposed portion 15B of the second input terminal 15 are exposed. The recesses 55 reach the bottom face 52 from the top face 51 in the thickness direction z. The plurality of recesses 55 are located on the two sides, in the second direction y, of the first input terminal 13, in the second direction y. As a result of providing the plurality of recesses 55, the creepage distance of the sealing resin 50 regarding the first input terminal 13 and the second input terminal 15 can be secured to be longer. This fact is favorable for improving the dielectric strength voltage of the semiconductor device A20.

As shown in FIGS. 27, 28, 31, and 32, in the semiconductor device A20, the groove 56 is recessed from the bottom face 52 in thickness direction z, and extends along the second direction y. The two ends, in the second direction y, of the groove 56 are connected to the pair of second side faces 54. The groove 56 includes pair of areas that are located apart from each other in the first direction x. The second metal layer 63 of the support substrate 60 is located between the pair of areas in the first direction x. As a result of providing the groove 56, the creepage distances of the sealing resin 50 from the first input terminal 13 and the second input terminal 15 to the output terminal 14 is secured to be longer. This fact is favorable for improving the dielectric strength voltage of the semiconductor device A20.

Next, the effects of the semiconductor device A20 will be described.

The semiconductor device A20 includes a conductive member (first conductive member 31) that is electrically joined to the electrodes of the plurality of semiconductor elements 20 (the second electrodes 212 of the pair of first elements 21A and the second electrode 212 of the fourth element 21D, in the semiconductor device A20) and the second obverse face 121 of the second conductive plate 12. The conductive member includes the main body portion 311, the plurality of first junction portions 312, the first connection portion 313, the second junction portion 314, and the third junction layer 35. The plurality of first junction portions 312 are individually and electrically joined to the electrodes of the plurality of semiconductor elements 20. The second junction portion 314 is electrically joined to the second obverse face 121. Joining of these portions of the conductive member are collectively performed. Therefore, according to the semiconductor device A20 as well, the manufacturing efficiency of the semiconductor device A20 can be improved while making it possible to handle more larger current.

In the semiconductor device A20, the first connection portion 313 of the first conductive member 31 includes a plurality of connection areas 313A that are located apart from each other in the second direction y. The plurality of connection areas 313A are individually connected to the plurality of first junction portions 312 of the first conductive member 31. Moreover, the plurality of connection areas 313A each incline, viewed along the second direction y, so as to separate from the first obverse face 111 of the first conductive plate 11 toward the main body portion 311 of the first conductive member 31 from one of the plurality of first junction portions 312. With this, fillets are likely to be formed in the respective plurality of first junction layers 33, the fillets being located on one side, in the first direction x, of the electrodes of the plurality of semiconductor elements 20. Moreover, in a cross section of the first conductive member 31 that includes a boundary between the plurality of connection areas 313A and the main body portion 311 and in which the first direction x is an off-plane direction, the second moment of area at the cross section decreases, and therefore bending of the first connection portion 313 relative to the main body portion 311 can be more facilitated.

The present disclosure is not limited to the abovementioned embodiment. Various design changes can be freely implemented with respect to the specific configuration of each part of the present disclosure.

The present disclosure includes the configurations described in the following Clauses.

Clause 1.

A semiconductor device including:

a first conductive plate having a first obverse face facing in a thickness direction;

a second conductive plate that has a second obverse face facing in the same direction, in the thickness direction, as the first obverse face, and is located apart from the first conductive plate in a first direction perpendicular to the thickness direction;

a plurality of semiconductor elements that are joined to the first obverse face and include electrodes that face in the same direction, in the thickness direction, as the first obverse face; and

a conductive member that is electrically joined to the electrodes of the plurality of semiconductor elements and the second obverse face,

wherein the conductive member includes a main body portion, a plurality of first junction portions that are individually and electrically joined to the electrodes of the plurality of semiconductor elements, a second junction portion that is electrically joined to the second obverse face, a first connection portion that connects the main body portion and the plurality of first junction portions, and a second connection portion that connects the main body portion and the second junction portion.

Clause 2.

The semiconductor device according to clause 1, wherein the plurality of first junction portions each include an overlapping area that overlaps with the electrode of one of the plurality of semiconductor elements, as viewed along the thickness direction, and

the areas of the overlapping areas are each 70% or more of each of the areas of the electrodes of the plurality of semiconductor elements, as viewed along the thickness direction.

Clause 3.

The semiconductor device according to clause 2, wherein at least a portion of the main body portion overlaps with the first obverse face, as viewed along the thickness direction.

Clause 4.

The semiconductor device according to clause 2 or 3, wherein the plurality of semiconductor elements are arranged along a second direction perpendicular to both of the thickness direction and the first direction, and

the main body portion extends along the second direction.

Clause 5.

The semiconductor device according to clause 4, wherein the first connection portion includes a plurality of connection areas that are located apart from each other in the second direction, and

the plurality of connection areas are individually connected to the plurality of first junction portions.

Clause 6.

The semiconductor device according to clause 5, wherein the plurality of connection areas are each inclined, as viewed along the second direction, away from the first obverse face while extending from the corresponding one of the plurality of first junction portions toward the main body portion.

Clause 7.

The semiconductor device according to clause 6, wherein the size of the acute angle formed between each of the plurality of first junction portions and the corresponding one of the plurality of connection areas connected thereto, as viewed along the second direction, is 30° or more and 60° or less.

Clause 8.

The semiconductor device according to any of clauses 2 to 7, further including a plurality of first junction layers that have conductivity, and individually and electrically join the plurality of first junction portions and the electrodes of the plurality of semiconductor elements,

wherein the plurality of first junction layers each include a portion that extends outward from the overlapping area of corresponding one of the plurality of first junction portions, as viewed along the thickness direction.

Clause 9.

The semiconductor device according to clause 8, wherein the plurality of first junction layers contain tin.

Clause 10.

The semiconductor device according to clause 9, wherein the thickness of each of the plurality of first junction portions is twice or less of a maximum thickness of the corresponding one of the plurality of first junction layers that is in contact therewith.

Clause 11.

The semiconductor device according to clause 10, wherein the maximum thickness of each of the plurality of first junction layers is 100 μm or more.

Clause 12.

The semiconductor device according to any of clauses 8 to 11, wherein the plurality of first junction portions each include an opening that passes through in the thickness direction, and

the plurality of first junction layers are in contact with inner circumferential surfaces of the respective first junction portions that each define the opening.

Clause 13.

The semiconductor device according to any of clauses 8 to 12, further including a second junction layer that has conductivity and electrically joins the second junction portion and the second obverse face,

wherein the second junction layer is made of the same material as the plurality of first junction layer.

Clause 14.

The semiconductor device according to any of clauses 1 to 13, wherein the first conductive plate, the second conductive plate, and the conductive member each contain copper.

Clause 15.

The semiconductor device according to any of clauses 1 to 14, wherein the thicknesses of the first conductive plate and the second conductive plate are larger than a maximum thickness of the conductive member.

Clause 16.

The semiconductor device according to any of clauses 1 to 15, wherein the second connection portion is inclined, viewed along an in-plane direction of the second obverse face, away from the second obverse face while extending from the second junction portion toward the main body portion.

Clause 17.

The semiconductor device according to any of clauses 1 to 16, further including a sealing resin that covers the plurality of semiconductor elements and the conductive member,

wherein the sealing resin is in contact with the first obverse face and the second obverse face.

Clause 18.

The semiconductor device according to clause 17, wherein the first conductive plate has a first reverse face that faces in a direction opposite to the first obverse face, in the thickness direction,

the second conductive plate has a second reverse face that faces in a direction opposite to the second obverse face, in the thickness direction, and

the first reverse face and the second reverse face are exposed from the sealing resin.

Clause 19.

The semiconductor device according to any of clauses 1 to 18, wherein at least one of the plurality of semiconductor elements includes a compound semiconductor substrate.

Clause 20.

The semiconductor device according to clause 19, wherein the compound semiconductor substrate contains silicon carbide.

### REFERENCE NUMERALS

A10, A20: Semiconductor device 11: First conductive plate
111: First obverse face 112: First reverse face
12: Second conductive plate 121: Second obverse face
122: Second reverse face 13: First input terminal
13A: Covered portion 13B: Exposed portion
14: Output terminal 14A: Covered portion
14B: Exposed portion 15: Second input terminal
15A: Covered portion 15B: Exposed portion
161: First gate terminal 161A: Covered portion
161B: Exposed portion 162: Second gate terminal
162A: Covered portion 162B: Exposed portion
171: First detection terminal 171A: Covered portion
171B: Exposed portion 172: Second detection terminal
172A: Covered portion 172B: Exposed portion
181: First diode terminal 182: Second diode terminal
20: Semiconductor element 21: Switching element
21A: First element 21B: Second element
21C: Third element 21D: Fourth element
211: First electrode 212: Second electrode
213: Third electrode 214: Fourth electrode
215: Fifth electrode 22: Protection element
22A: First diode 22B: Second diode
221: Upper face electrode 222: Lower face electrode
23: Die bonding layer 31: First conductive member
311: Main body portion 312: First junction portion
312A: Opening 312B: Overlapping area
313: First connection portion 313A: Connection area
314: Second junction portion 315: Second connection portion
32: Second conductive member 321: Main body portion
322: Third junction portion 322A: Opening
323: Third connection portion 324: Fourth junction portion
325: Fourth connection portion 326: Intermediate portion
327: Transverse beam portion 33: First junction layer
34: Second junction layer 35: Third junction layer
36: Fourth junction layer 41: Gate wire
42: Detection wire 43: Diode wire
50: Sealing resin 51: Top face
52: Bottom face 53: First side face
54: Second side face 55: Recess
56: Groove 57: First protrusion
571: Attachment hole 58: Second protrusion
60: Support substrate 61: Insulating layer
62: First metal layer 63: Second metal layer
69: Junction layer 70: Control interconnect
70A: First interconnect 70B: Second interconnect
71: Insulating layer 72: Interconnect layer
721: First interconnect layer 722: Second interconnect layer
723: Third interconnect layer 73: Metal layer
74: Holder 75: Covering layer
78: Junction layer 79: Holder junction layer
z: Thickness direction x: First direction y: Second direction

1. A semiconductor device comprising:
a first conductive plate having a first obverse face facing in a thickness direction;
a second conductive plate that has a second obverse face facing in a same direction, in the thickness direction, as the first obverse face, and is located apart from the first conductive plate in a first direction perpendicular to the thickness direction;
a plurality of semiconductor elements that are joined to the first obverse face and include respective electrodes that face in the same direction, in the thickness direction, as the first obverse face; and
a conductive member that is electrically joined to the electrodes of the plurality of semiconductor elements and the second obverse face,
wherein the conductive member includes a main body portion, a plurality of first junction portions that are individually and electrically joined to the electrodes of the plurality of semiconductor elements, a second junction portion that is electrically joined to the second obverse face, a first connection portion that connects the main body portion and the plurality of first junction portions, and a second connection portion that connects the main body portion and the second junction portion.

2. The semiconductor device according to claim 1, wherein the plurality of first junction portions each include an overlapping area that overlaps with the electrode of one of the plurality of semiconductor elements, as viewed along the thickness direction, and
the areas of the overlapping areas are each 70% or more of each of the areas of the electrodes of the plurality of semiconductor elements, as viewed along the thickness direction.

3. The semiconductor device according to claim 2, wherein at least a portion of the main body portion overlaps with the first obverse face, as viewed along the thickness direction.

4. The semiconductor device according to claim 2, wherein the plurality of semiconductor elements are arranged along a second direction perpendicular to the thickness direction and the first direction, and the main body portion extends along the second direction.

5. The semiconductor device according to claim 4, wherein the first connection portion includes a plurality of connection areas that are located apart from each other in the second direction, and the plurality of connection areas are individually connected to the plurality of first junction portions.

6. The semiconductor device according to claim 5, wherein the plurality of connection areas are each inclined, as viewed along the second direction, away from the first obverse face while extending from the corresponding one of the plurality of first junction portions toward the main body portion.

7. The semiconductor device according to claim 6, wherein the size of the acute angle formed between each of the plurality of first junction portions and the corresponding one of the plurality of connection areas connected thereto, as viewed along the second direction, is 30° or more and 60° or less.

8. The semiconductor device according claim 2, further comprising a plurality of first junction layers that have conductivity, and individually and electrically join the plurality of first junction portions and the electrodes of the plurality of semiconductor elements,
wherein the plurality of first junction layers each include a portion that extends outward from the overlapping area of corresponding one of the plurality of first junction portions, viewed along the thickness direction.

9. The semiconductor device according to claim 8, wherein the plurality of first junction layers each contain tin.

10. The semiconductor device according to claim 9, wherein a thickness of each of the plurality of first junction portions is twice or less of a maximum thickness of the corresponding one of the plurality of first junction layers that is in contact therewith.

11. The semiconductor device according to claim 10, wherein a maximum thickness of each of the plurality of first junction layers is 100 μm or more.

12. The semiconductor device according to claim 8, further comprising a second junction layer that has conductivity and electrically joins the second junction portion and the second obverse face, wherein the second junction layer is made of a same material as the plurality of first junction layer.

13. The semiconductor device according to claim 1, wherein the first conductive plate, the second conductive plate, and the conductive member each contain copper.

14. The semiconductor device according to claim 1, wherein thicknesses of the first conductive plate and the second conductive plate are larger than a maximum thickness of the conductive member.

15. The semiconductor device according to claim 1, wherein the second connection portion is inclined, as viewed along an in-plane direction of the second obverse face, away from the second obverse face while extending from the second junction portion toward the main body portion.
